(19) United States
(12) Patent Application Publication
(10) Pub. No.: US 2011/0304243 A1
(43) Pub. Date: Dec. 15, 2011

(54) Thin-Film Piezoelectric Acoustic Wave Resonator and High-Frequency Filter

(75) Inventors: Atsushi Isobe, Kodaira (JP); Kengo Asai, Hachioji (JP)

(73) Assignee: Hitachi, Ltd., Chiyoda-ku, Tokyo (JP)

(21) Appl. No.: 13/201,344

(22) PCT Filed: Feb. 18, 2010
(86) PCT No.: PCT/JP2010/052447

§ 371 Date: Aug. 12, 2011

(30) Foreign Application Priority Data
Mar. 6, 2009 (JP) 2009053521

(51) Int. Cl. H01L 41/04

(52) U.S. Cl. 310/326

(57) ABSTRACT

A thin-film piezoelectric acoustic wave resonator that has a large k2, can trap acoustic energy in a resonating part, does not excite spurious resonance, or can finely adjust resonance frequency and a high-frequency filter using the thin-film piezoelectric acoustic wave resonator are provided without increasing the number of processes. At both ends of a vibrating part (1), fixing parts (8) are physically connected, and between the vibrating part (1) and each of the fixing parts (8), an acoustic insulating part (10) and a phase rotating part (11) are physically connected. As with the vibrating part (1), the acoustic insulating part (10) and the phase rotating part (11) are made up of an upper metal film (3), a piezoelectric thin film, and a lower metal film, and an acoustic wave reflector (6) is provided on each of an upper surface, a lower surface, and side surfaces of the vibrating part (1), the acoustic insulating part (10), and the phase rotating part (11). The vibrating part (1) has a width smaller than its length (La) and also smaller than its thickness, and width/thickness is smaller than 1.

### TECHNICAL FIELD

The present invention relates to a technique effectively applied to a high-frequency resonator which uses a piezoelectric effect or a reverse piezoelectric effect of a thin-film piezoelectric body and also utilizes a resonance phenomenon of acoustic waves (hereinafter abbreviated as a thin-film piezoelectric acoustic wave resonator) and to a high-frequency filter using the thin-film piezoelectric acoustic wave resonator.

### BACKGROUND ART

Acoustic wave resonators suitable for high-frequency filters include an FBAR (Film Bulk Acoustic wave Resonator) and an SMR (Solidly Mounted Resonator).

For example, Japanese Unexamined Patent Application Publication No. 2002-335141 (Patent Document 1) discloses an FBAR-type thin-film bulk acoustic resonator in which resonators with different resonance frequencies can be fabricated on the same insulating substrate by forming a load layer on an upper electrode so as to cover this upper electrode.

Also, International Patent Publication WO 01/06647 (Patent Document 2) discloses an SMR-type thin-film bulk acoustic resonator which vibrates in a piston mode with a load layer formed around an upper electrode.

Furthermore, Japanese Unexamined Patent Application Publication No. 2007-295310 (Patent Document 3) discloses a BAW resonator in which piezoelectric transducer elements of a piezoelectric transducer part are each formed in a columnar shape whose longitudinal direction coincides with a thickness direction of a lower electrode and are disposed in a two-dimensional array on the lower electrode.

Still further, “Bulk-Acoustic Wave Filters: Performance Optimization and Volume Manufacturing”, R. Aigner and seven others, IEEE MTT-S Digest, 2003, pp. 2001 to 2004 (Non-Patent Document 1) discloses an SMR-type thin-film bulk acoustic filter in which, in order to produce resonators with different resonance frequencies, an auxiliary metal layer is added onto a surface electrode layer to shift the resonance frequencies.

Still further, “Method of Fabricating Multiple-frequency Film Bulk Acoustic Resonators in a Single Chip”, L. Wang and five others, IEEE Frequency Control Symposium Digest, 2006, p. 179 (Non-Patent Document 2) describes a technique in which, in order to produce a plurality of FBAR-type resonators with different resonance frequencies on one chip, an additional adjustment layer is provided on a surface electrode layer and a pattern for adjusting the width and pitch of the adjustment layer is controlled, thereby making it possible to adjust resonance frequencies.

Still further, “Review and Comparison of Bulk Acoustic Wave FBAR, SMR Technology”, R. Ruby, IEEE Ultrasonics Symposium Proceedings, 2007, pp. 1029 to 1040 (Non-Patent Document 3) discusses an electromechanical coupling coefficient (k2) of an acoustic wave resonator in detail.

Still further, “Single-crystal aluminum nitride nanomechanical resonators”, A. N. Cleland and two others, Appl. Phys. Lett., Vol. 79, 2001, pp. 2070 to 2072 (Non-Patent Document 4) describes a Flexural resonator using a single-crystal AlN film.

### PRIOR ART DOCUMENTS

### Patent Documents

Patent Document 1: Japanese Unexamined Patent Application Publication No. 2002-335141
Patent Document 2: International Patent Publication WO 01/06647
Patent Document 3: Japanese Unexamined Patent Application Publication No. 2007-295310

### Non-Patent Documents

Non-Patent Document 1: “Bulk-Acoustic Wave Filters: Performance Optimization and Volume Manufacturing”, R. Aigner, J. Kaitila, J. Ella, L. Elbrecht, W. Nessler, M. Handtmann, T. Herzog, and S. Marksteiner, IEEE MTT-S Digest, 2003, pp. 2001 to 2004
Non-Patent Document 2: “Method of Fabricating Multiple-frequency Film Bulk Acoustic Resonators in a Single Chip”, L. Wang, E. Ginsburg, D. Diamant, Q. Ma, Z. Huang, and Z. Suo, IEEE Frequency Control Symposium Digest, 2006, p. 179
Non-Patent Document 3: “Review and Comparison of Bulk Acoustic Wave FBAR, SMR Technology”, R. Ruby, IEEE Ultrasonics Symposium Proceedings, 2007, pp. 1029 to 1040
Non-Patent Document 4: “Single-crystal aluminum nitride nanomechanical resonators”, A. N. Cleland, M. Pophristic, and I. Ferguson, Appl. Phys. Lett., Vol. 79, 2001, pp. 2070 to 2072

### SUMMARY OF THE INVENTION

### Problems to be Solved by the Invention

In general, an acoustic wave resonator with a resonance frequency of 10 MHz or higher suitable for a high-frequency filter is provided with: a vibrating part (resonating part) made up of a piezoelectric thin film having a planar (membrane) structure with a sufficiently large size with respect to thickness (structure in which, among portions in X, Y, and Z axis directions of a resonating part, those in two directions (X axis direction and Y axis direction) other than the thickness direction (Z axis direction) are sufficiently large) and a first metal thin film and a second metal thin film which are present with interposing a part of the piezoelectric thin film therebetween; and acoustic reflectors. The first metal thin film functions as an upper electrode (upper metal film), and the second metal thin film functions as a lower electrode (lower metal film). The piezoelectric thin film is polarized in the thickness direction. An alternating electric field generated by an alternating voltage applied between the upper electrode and the lower electrode causes vibrations having stretchable components in the thickness direction of the piezoelectric thin film by a piezoelectric effect or a reverse piezoelectric effect. Since the vibrating part has a planar structure, vibrations having stretchable components in an in-plane direction do not occur, or occur as spurious components at most.

The vibrating part made up of the upper metal film, the piezoelectric thin film, and the lower metal film is vertically interposed between the acoustic reflectors. An interface between a solid and gas or vacuum functions as an effective acoustic reflection surface. In an FBAR, gas or vacuum is present above and below the resonator, and the gas or vacuum is taken as an acoustic reflector. In an SMR, gas or vacuum is present above the upper metal film, and a Bragg reflector is placed below the lower metal film. Ideally, vibrations having stretchable components in the in-plane direction do not occur, and therefore acoustic waves generated at the piezoelectric thin film are trapped in the resonator.

The exited acoustic waves resonate when its half wavelength coincides with the sum of the film thickness of the upper metal film, the film thickness of the piezoelectric thin film, and the film thickness of the lower metal film. The resonance frequency is represented by a ratio between an acoustic velocity and a wavelength of an acoustic wave (twice the sum of the film thickness of the upper metal film, the film thickness of the piezoelectric thin film, and the film thickness of the lower metal film).

However, as for the high-frequency acoustic wave resonator disclosed in Patent Document 1 or 2 described above or Non-Patent Document 1 or 2 described above, various technical problems described below are present.

<Problem 1>

In Non-Patent Document 3, k2 (electromechanical coupling coefficient) of the acoustic wave resonator disclosed in Patent Document 1 or 2 or Non-Patent Document 1 or 2 is discussed in detail. According to Non-Patent Document 3, it is disclosed that k2 can be increased by using a heavy metal for an electrode material and k2 of the FBAR type is larger than k2 of the SMR type. Furthermore, although electric characteristics of the high-frequency filter are improved as k2 becomes larger, even if a heavy metal is used for the electrode material, the FBAR and the SMR, which are acoustic wave resonators for high frequency disclosed in Patent Document 1 or 2 or Non-Patent Document 1 or 2, can have 6.5 to 7% at most. For this reason, a resonator having a further larger k2 needs to be used in order to achieve a high-frequency filter with further better electric characteristics, but a further improvement in electric characteristics of the high-frequency filter cannot be expected in the FBAR and the SMR.

<Problem 2>

In the acoustic wave resonator for high frequency disclosed in Patent Document 1 or Non-Patent Document 1 or 2, a phenomenon described in Patent Document 2, that is, spurious vibrations having stretchable components in the in-plane direction occurs slightly, and acoustic energy leaks from the vibrating part (portion having a three-layer structure formed of the upper metal film, the piezoelectric thin film, and the lower metal film and having acoustic reflectors provided above and below the three-layer structure) through the piezoelectric thin film. Therefore, a Q value of the resonator is degraded, and filter loss increases.

Note that, although Patent Document 2 discloses a method of trapping acoustic energy in the vibrating part, it is required to add a new film or perform complex processing in the FBAR-type resonator, and the manufacturing cost is increased. On the other hand, since leakage of acoustic energy from an electric line connected to the upper and lower electrodes is not taken into consideration in the SMR-type resonator, it is impossible to trap the acoustic energy in a resonator or a filter in practice. Otherwise, complex processing is required, and the manufacturing cost is increased.

<Problem 3>

In the acoustic wave resonator for high frequency disclosed in Patent Document 1 or Non-Patent Document 1 or 2, a phenomenon described in Patent Document 2, that is, a phenomenon of generating spurious vibrations occurs because a Lamb wave is also exited in addition to a fundamental wave. Therefore, a Q value of the resonator is degraded, and filter loss increases.

Note that, although Patent Document 2 discloses an exciting method in a piston mode in which excitation of a Lamb wave is suppressed, it is required to add a new film or perform complex processing, and the manufacturing cost is increased.

<Problem 4>

In a filter using an acoustic wave resonator typified by a ladder type, a band pass filter is achieved by increasing the resonance frequency of a series-arm resonator more than the resonance frequency of a parallel-arm resonator. Therefore, it is required to form acoustic wave resonators having different resonance frequencies on the same substrate.

Since the resonance frequency is controlled by the film thickness, in order to form paired acoustic wave resonators having different resonance frequencies on the same substrate, as disclosed in Patent Document 1 or Non-Patent Document 1, it is necessary to form an upper metal film on both resonators, leave the upper metal film of one resonator as it is, and then newly add a load film onto the upper metal film of the other resonator. Therefore, the number of processes disadvantageously increases, and the manufacturing cost is increased.

Also, in Patent Document 1 or Non-Patent Document 1, since the film thickness of the load film determines a difference in frequency, extremely high film-thickness accuracy is required. For this reason, an expensive film-forming apparatus is required, and the manufacturing cost is increased.

Note that, according to Non-Patent document 2, resonance frequencies can be adjusted by controlling the width and pitch of the adjustment layer with a patterning process. However, like the technique disclosed in Patent Document 1 or Non-Patent Document 1, a film has to be newly added onto the upper metal film, and the number of processes is not changed from that of the method of Patent Document 1 or Non-Patent Document 1. Therefore, the manufacturing cost is increased.

A first object of the present invention is to provide a thin-film piezoelectric acoustic wave resonator with large k2 and a high-frequency filter using the thin-film piezoelectric acoustic wave resonator without increasing the number of processes.

A second object of the present invention is to provide a thin-film piezoelectric acoustic wave resonator which traps acoustic energy in a resonating part and a high-frequency filter using the thin-film piezoelectric acoustic wave resonator without increasing the number of processes.

A third object of the present invention is to provide a thin-film piezoelectric acoustic wave resonator not exciting spurious resonance and a high-frequency filter using the thin-film piezoelectric acoustic wave resonator without increasing the number of processes.

A fourth object of the present invention is to provide a thin-film piezoelectric acoustic wave resonator allowing fine adjustment of resonance frequency and a high-frequency filter using the thin-film piezoelectric acoustic wave resonator without increasing the number of processes.

The above and other objects and novel characteristics of the present invention will be apparent from the description of the present specification and the accompanying drawings.

### Means for Solving the Problems

The following is a brief description of an embodiment of the typical invention disclosed in the present application.

This embodiment is a thin-film piezoelectric acoustic wave resonator including a vibrating part having a laminated structure made up of a piezoelectric thin film and a pair of an upper metal film and a lower metal film which are present with interposing a part of the piezoelectric thin film therebetween. The vibrating part has a first dimension in a first direction in a plane orthogonal to a thickness direction of the vibrating part and has a second dimension in a second direction orthogonal to the first direction, the first dimension is smaller than the second dimension, and the first dimension is smaller than a third dimension of the vibrating part in the thickness direction, and an acoustic wave reflector is provided on each of an upper surface, a lower surface, and side surfaces of the vibrating part, a first fixing part mainly made of the same film as the piezoelectric thin film is provided at one end of the vibrating part in the second direction, and a second fixing part mainly made of the same film as the piezoelectric thin film is provided at the other end of the vibrating part in the second direction.

Also, this embodiment is a high-frequency filter having an input terminal, an output terminal, and a plurality of thin-film piezoelectric acoustic wave resonators electrically connected between the input terminal and the output terminal at predetermined intervals in a parallel arm or a series arm. The thin-film piezoelectric acoustic wave resonator includes a vibrating part having a laminated structure made up of a piezoelectric thin film and a pair of an upper metal film and a lower metal film which are present with interposing a part of the piezoelectric thin film therebetween, and the vibrating part has a first dimension in a first direction in a plane orthogonal to a thickness direction of the vibrating part and has a second dimension in a second direction orthogonal to the first direction, the first dimension is smaller than the second dimension, and the first dimension is smaller than a third dimension of the vibrating part in the thickness direction, and an acoustic wave reflector is provided on each of an upper surface, a lower surface, and side surfaces of the vibrating part, a first fixing part mainly made of the same film as the piezoelectric thin film is provided at one end of the vibrating part in the second direction, and a second fixing part mainly made of the same film as the piezoelectric thin film is provided at the other end of the vibrating part in the second direction.

### Effects of the Invention

The effects achieved by an embodiment of the typical aspect of the invention disclosed in the present application will be briefly described below.

It is possible to provide a thin-film piezoelectric acoustic wave resonator that has a large k2, can trap acoustic energy in a resonating part, does not excite spurious resonance, or can finely adjust resonance frequency and a high-frequency filter using the thin-film piezoelectric acoustic wave resonator without increasing the number of processes.

### BRIEF DESCRIPTIONS OF THE DRAWINGS

FIG. 1 is a schematic top view of a beam-type resonator according to a first embodiment of the present invention;

FIG. 2 is a schematic cross-sectional view of the beam-type resonator taken along an A-A′ line of FIG. 1;

FIG. 3 is a schematic cross-sectional view of the beam-type resonator taken along a B-B′ line of FIG. 1;

FIG. 4 is a perspective schematic view of a vibrating part of the beam-type resonator according to the first embodiment of the present invention;

FIG. 5 is a graph showing a relation between k2 and W/h of an element according to the first embodiment of the present invention;

FIG. 6 is a schematic top view of a beam-type resonator according to a second embodiment of the present invention;

FIG. 7 is a schematic cross-sectional view of the beam-type resonator taken along a C-C′ line of FIG. 6;

FIG. 8 is a schematic cross-sectional view of the beam-type resonator taken along a D-D′ line of FIG. 6;

FIG. 9 is a graph showing a dispersion curve of an element in a TWE mode according to the second embodiment of the present invention;

FIG. 10 is a graph showing a relation among fd, fb, and ft and W/h of the element in the TWE mode according to the second embodiment of the present invention;

FIG. 11 is a schematic top view of a beam-type resonator according to a third embodiment of the present invention;

FIG. 12 is a schematic cross-sectional view of the beam-type resonator taken along an E-E′ line of FIG. 11;

FIG. 13 is a schematic cross-sectional view of the beam-type resonator taken along an F-F′ line of FIG. 11;

FIG. 14 is a graph showing a relation among fd, fb, and ft and W/h of the element in the TWE mode according to the third embodiment of the present invention;

FIG. 15 is a schematic top view of a beam-type resonator according to a fourth embodiment of the present invention;

FIG. 16 is a schematic cross-sectional view of the beam-type resonator taken along a G-G′ line of FIG. 15;

FIG. 17 is a schematic cross-sectional view of the beam-type resonator taken along an H-H′ line of FIG. 15;

FIG. 18 is a graph showing a relation among fd, fb, and ft and W/h of the element in the TWE mode according to the fourth embodiment of the present invention;

FIG. 19 is a graph showing frequency characteristics of impedances of the element according to the fourth embodiment of the present invention;

FIG. 20 is a graph showing frequency characteristics of impedances of the beam-type resonator of the element in which the width of a phase rotating part is made to coincide with the width of a vibrating part according to the fourth embodiment of the present invention;

FIG. 21 is a schematic top view of a beam-type resonator according to a fifth embodiment of the present invention;

FIG. 22 is a schematic cross-sectional view of the beam-type resonator taken along an I-I′ line of FIG. 21;

FIG. 23 is a schematic cross-sectional view of the beam-type resonator taken along a J-J′ line of FIG. 21;

FIG. 24 is a graph showing a relation among fd, fb, and ft and W/h of the element in the TWE mode according to the fifth embodiment of the present invention;

FIG. 25 is a schematic top view of a beam-type resonator according to a sixth embodiment of the present invention;

FIG. 26 is a schematic cross-sectional view of the beam-type resonator taken along a K-K′ line of FIG. 25;

FIG. 27 is a schematic cross-sectional view of the beam-type resonator taken along an L-L′ line of FIG. 25;

FIG. 28 is a graph showing frequency characteristics of impedances of the element according to the sixth embodiment of the present invention;

FIG. 29 is a schematic top view of a beam-type resonator according to a seventh embodiment of the present invention;

FIG. 30 is a schematic cross-sectional view of the beam-type resonator taken along an M-M′ line of FIG. 29;

FIG. 31 is a schematic cross-sectional view of the beam-type resonator taken along an N-N′ line of FIG. 29;

FIG. 32 is a graph showing frequency characteristics of impedances of the element according to the seventh embodiment of the present invention;

FIG. 33 is a schematic top view of a beam-type resonator according to an eighth embodiment of the present invention;

FIG. 34 is a schematic top view of a beam-type resonator according to a ninth embodiment of the present invention;

FIG. 35 is a graph showing frequency characteristics of impedances of the element according to the ninth embodiment of the present invention;

FIG. 36A is a schematic top view of a first example of a beam-type resonator group according to a tenth embodiment of the present invention;

FIG. 36B is a schematic top view of a second example of a beam-type resonator group according to the tenth embodiment of the present invention;

FIG. 37 is an equivalent circuit diagram of a high-pass filter according to an eleventh embodiment of the present invention;

FIG. 38 is a frequency characteristic diagram of a low-pass filter according to the eleventh embodiment of the present invention;

FIG. 39 is a frequency characteristic diagram of a low-pass filter according to the eleventh embodiment of the present invention;

FIG. 40 is a graph showing a relation between series resonance frequency and parallel resonance frequency and W/h of a beam-type resonator according to the eleventh embodiment of the present invention;

FIG. 41 is an equivalent circuit diagram of a low-pass filter according to the eleventh embodiment of the present invention;

FIG. 42 is a frequency characteristic diagram of a low-pass filter according to the eleventh embodiment of the present invention;

FIG. 43 is a frequency characteristic diagram of a low-pass filter according to the eleventh embodiment of the present invention;

FIG. 44 is an equivalent circuit diagram of a band-pass filter according to the eleventh embodiment of the present invention;

FIG. 45 is a frequency characteristic diagram of a band-pass filter according to the eleventh embodiment of the present invention;

FIG. 46 is a schematic top view of a beam-type resonator according to a twelfth embodiment of the present invention;

FIG. 47 is a schematic cross-sectional view of the beam-type resonator taken along an O-O′ line of FIG. 46;

FIG. 48 is a schematic top diagram of a P area of FIG. 46;

FIG. 49 is a graph showing W/h dependency of resonance frequencies in a TWE mode and a spurious mode according to the twelfth embodiment of the present invention;

FIG. 50 is a schematic top view of a beam-type resonator according to a thirteenth embodiment of the present invention;

FIG. 51 is a schematic cross-sectional view of the beam-type resonator taken along a Q-Q′ line of FIG. 50;

FIG. 52 is a schematic cross-sectional view of the beam-type resonator taken along an R-R′ line of FIG. 50;

FIG. 53 is a schematic top view of a high-frequency device according to a fourteenth embodiment of the present invention; and

FIG. 54 is an equivalent circuit diagram of the high-frequency device according to the fourteenth embodiment of the present invention.

### BEST MODE FOR CARRYING OUT THE INVENTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Also, the FBAR-type or SMR-type resonator is a resonator using a plane wave (bulk wave). However, since a thin-film piezoelectric acoustic wave resonator described in the following embodiments uses a non-plane wave (non-bulk wave) propagating through a one-dimensional structure (beam structure), the thin-film piezoelectric acoustic wave resonator to be described in the following embodiments is referred to as a beam-type resonator in order to clarify that it is a resonator different from an FBAR-type resonator and an SMR-type resonator.

Also, components having the same function are denoted by the same reference symbols throughout the drawings for describing the embodiments, and the repetitive description thereof will be omitted. Furthermore, in the drawings used in the following embodiments, hatching is used even in a plan view so as to make the drawings easy to see. Hereinafter, embodiments of the present invention will be described in detail based on the drawings.

### First Embodiment

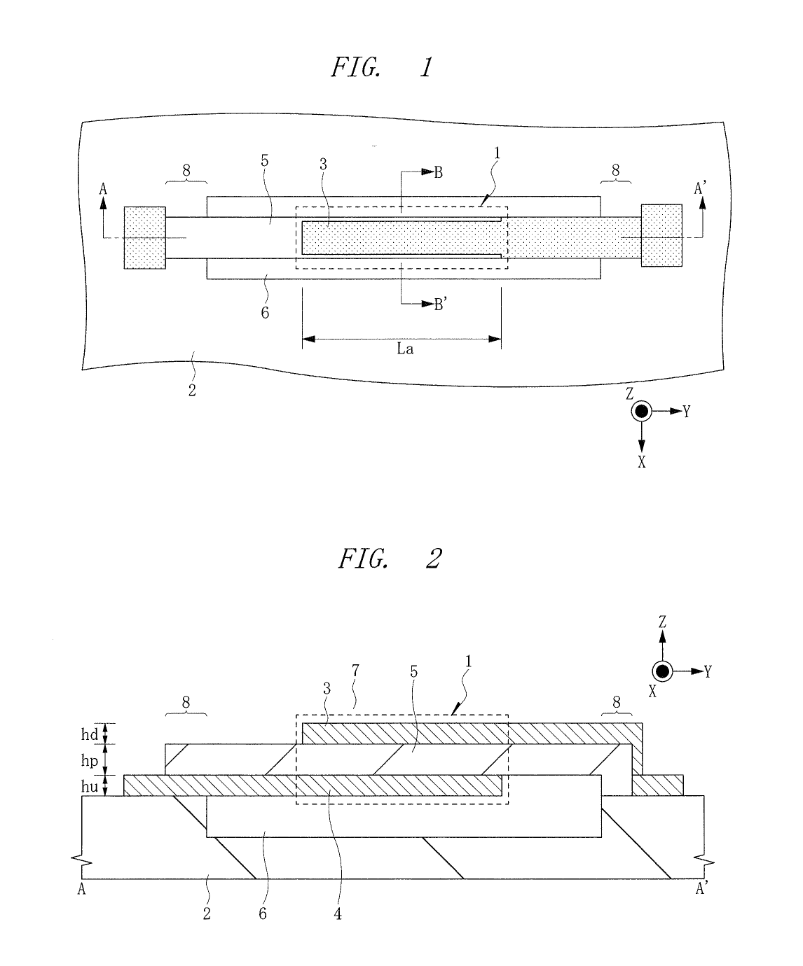

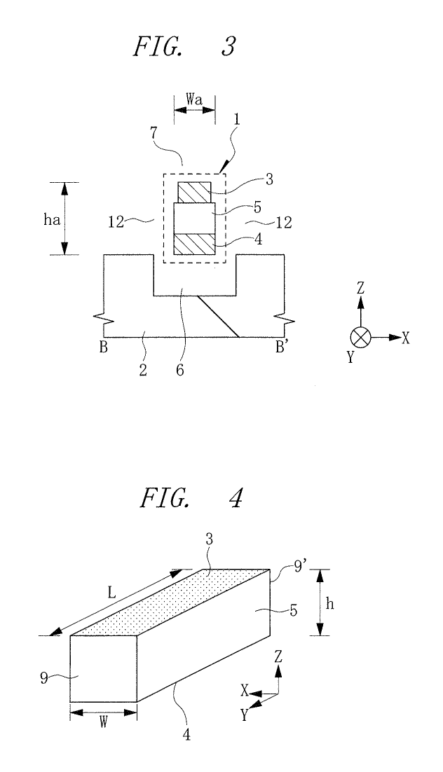

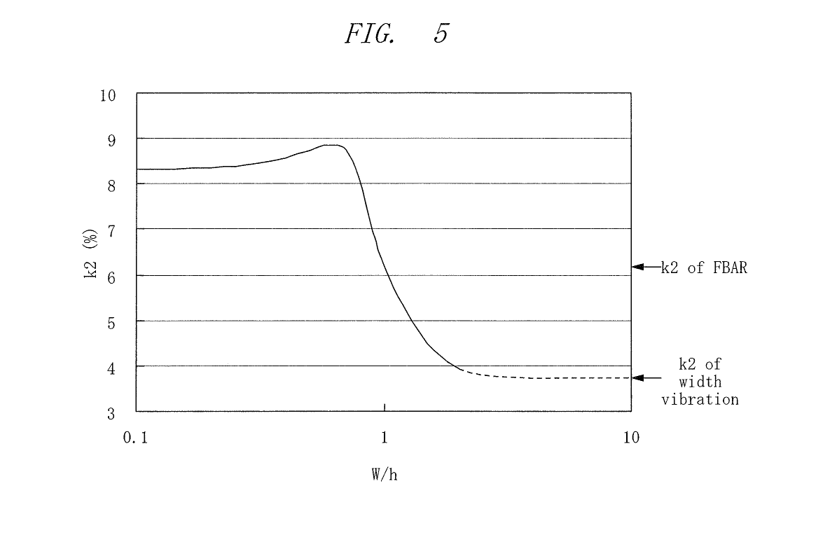

A beam-type resonator according to the first embodiment will be described with reference to FIG. 1 to FIG. 3. FIG. 1 is a schematic top view of the beam-type resonator, FIG. 2 is a schematic cross-sectional view of the beam-type resonator taken along an A-A′ line of FIG. 1, and FIG. 3 is a schematic cross-sectional view of the beam-type resonator taken along a B-B′ line of FIG. 1.

As shown in FIG. 1 to FIG. 3, the beam-type resonator is formed on an insulating substrate 2. A vibrating part 1 of this beam-type resonator has a laminated structure (thickness ha) including a piezoelectric thin film 5 (film thickness hp) and a pair of an upper metal film (upper electrode) 3 (film thickness hd) and a lower metal film (lower electrode) 4 (film thickness hu) which are present with interposing a part of this piezoelectric thin film 5 therebetween. The thickness ha is, for example, about 1 to 2 μm. The vibrating part 1 has an upper surface surrounded by an upper acoustic wave reflector (upper acoustic reflector) 7, a lower surface surrounded by a lower acoustic wave reflector (lower acoustic reflector) 6, and side surfaces surrounded by side acoustic wave reflectors (side acoustic reflectors) 12.

In the first embodiment, the upper metal film 3 and the lower metal film 4 are both made of an aluminum film formed by a film-forming apparatus, and the piezoelectric thin film 5 is made of an aluminum nitride film formed by a film-forming apparatus. It is needless to say that, as each of the upper metal film 3 and the lower metal film 4, a thin film made of another conductive material such as copper, platinum, ruthenium, molybdenum, tungsten, or gold may be used in place of an aluminum film. Similarly, it is needless to say that, as the piezoelectric thin film 5, a thin film made of another piezoelectric material such as zinc oxide, lithium niobate, lithium tantalate, potassium niobate, tantalum pentoxide, lead titanate, or barium titanate may be used in place of an aluminum nitride film.

Note that the film-forming apparatus described in the first embodiment is typified by a sputter apparatus, a vapor deposition apparatus, or a CVD apparatus, which forms a thin film by directly stacking molecules, atoms, ions or clusters thereof on a substrate or by stacking layers together with a chemical reaction. Also, the thin film described in the first embodiment is a film produced by this film-forming apparatus, and does not include a sintered object produced by sintering or a bulk object formed by the hydrothermal synthesis method or the Czochralski method irrespectively of the thickness.

For applying an electric field to the piezoelectric thin film 5, the upper metal film 3 approximately faces the corresponding lower metal film 4 with interposing the piezoelectric thin film 5 therebetween in the vibrating part 1. However, since the upper metal film 3 and the lower metal film 4 are different in position and shape of lead-out lines provided in a peripheral part, their planer shapes do not always coincide with each other. In the first embodiment, it is assumed that a range where the upper metal film 3 and the lower metal film 4 face each other in their planer shapes with respect to an Y axis direction, a range where the piezoelectric thin film 5 is present with respect to an X axis direction, and a region from a lower surface of the upper acoustic wave reflector 7 to an upper surface of the lower acoustic wave reflector 6 with respect to a Z axis direction are defined as the vibrating part 1.

A first dimension of the vibrating part 1 in the X axis direction (width Wa) is set to be smaller than a third dimension in the Z axis direction (thickness ha). On the other hand, a second dimension of the vibrating part 1 in the Y axis direction (length La) is set to be larger than the third dimension in the Z axis direction (thickness ha). The width Wa is, for example, about 0.6 μm, and the length La is, for example, about 100 μm. Therefore, the vibrating part 1 has a structure in a beam shape (structure sufficiently long only in one direction among the X, Y, and Z axis directions of the resonating part), and this is the difference from the structure of a vibrating part of the conventional FBAR having a planar structure.

The vibrating part 1 has an end in a plus Y axis direction and an end in a minus Y axis direction, and a fixing part 8 formed of the piezoelectric thin film 5 is physically connected to each of the ends in an indirect manner. The fixing part 8 may be formed to include the upper metal film 3 and the lower metal film 4, and may include other additional films. In a downward direction of the fixing part 8 (minus Z axis direction), no lower acoustic wave reflector 6 is provided. The fixing part 8 is physically connected to the insulating substrate 2 via the lower metal film 4 in the minus Y axis direction and is directly and physically connected to the insulating substrate 2 in the plus Y axis direction.

The insulating substrate 2 does not vibrate because it is sufficiently larger than the vibrating part 1. Vibrations of the vibrating part 1 flow into the insulating substrate 2 in some cases, but even in that case, since the vibrations are diffused over the entire insulating substrate 2, the amplitude of the insulating substrate 2 is sufficiently smaller than the amplitude of the vibrating part 1.

The fixing part 8 is formed of the piezoelectric thin film 5, which is a main vibrating medium of the vibrating part 1. Therefore, vibrations of a surface of the fixing part 8 on a vibrating part 1 side (in FIG. 2, a cross-section of the fixing part 8 on the vibrating part 1 side) leak to the insulating substrate 2. Also, since the insulating substrate 2 is sufficiently larger than the fixing part 8 or the vibrating part 1, the fixing part 8 substantially functions as a mechanical fixing portion.

When an alternating electrical signal is applied between the upper metal film 3 and the lower metal film 4, an alternating electric field is generated in the piezoelectric thin film 5 in the Z axis direction, and the piezoelectric thin film 5 stretches and contracts in the Z axis direction and the X axis direction. Thus, the vibrating part 1 vibrates. The vibrations in the Z axis direction and the vibrations in the X axis direction are shifted in phase by 180 degrees. This vibration mode is hereinafter referred to as a TWE mode (Thickness-Width Extensional mode).

Since the vibrations of the vibrating part 1 in the Y axis direction are those irrespective of main vibrations, the vibrations invite a decrease of k2 in the TWE mode. Also, since resonance occurs at a frequency different from that in the TWE mode, this resonance is spurious resonance in terms of electric characteristics of the resonator. In the first embodiment, since the vibrating part 1 is interposed between the fixing parts 8 in both of the plus Y axis direction and the minus Y axis direction, it does not stretch or contract in the Y axis direction. Also, since the vibrations of the vibrating part 1 in the Y axis direction have a frequency significantly different from those of the vibrations in the Z axis direction and the vibrations in the X axis direction, they are not coupled to the vibrations in the Z axis direction and the vibrations in the X axis direction.

When Wa/ha<1.05 is set, the vibrations in the Z axis direction and the vibrations in the X axis direction are coupled together, and resonance occurs at the same frequency. In this case, since effects of two piezoelectric constants, that is, a piezoelectric constant e33 and a piezoelectric constant e31 of the piezoelectric thin film 5 work synertistically, k2 is larger than those of FBAR vibrations stretching and contracting only in the Z axis direction (FBAR: vibrates only with the piezoelectric constant e33) or lateral vibrations stretching and contracting only in the X axis direction (vibrates only with the piezoelectric constant e31).

An optimum ratio between the width Wa and the thickness ha at which k2 becomes largest depends on an absolute value of a ratio between the piezoelectric constant e31 and the piezoelectric constant e33 of the vibrating part 1 (|e31/e33|) and a ratio between an elastic constant C11 and an elastic constant C33 (C11/C33). When the piezoelectric material is formed of a thin film made of, for example, aluminum nitride, zinc oxide, lithium niobate, lithium tantalate, potassium niobate, tantalum pentoxide, lead titanate, or barium titanate, k2 can be made largest by setting Wa/ha=0.6 as will be described further below.

By using a finite-element method, resonance characteristics of the beam-type resonator according to the first embodiment are studied in detail. FIG. 4 is a schematic diagram for describing a model used for computation. The piezoelectric thin film 5 is assumed to be in a shape of a rectangular parallelepiped with a width W in the X axis direction, a thickness h in the Z axis direction (1 μm), and a length L in the Y axis direction. Also, both end surfaces in the Y axis direction are each assumed to be a mechanical fixing surface 9 as a surface of the fixing part 8 on the vibrating part 1 side.

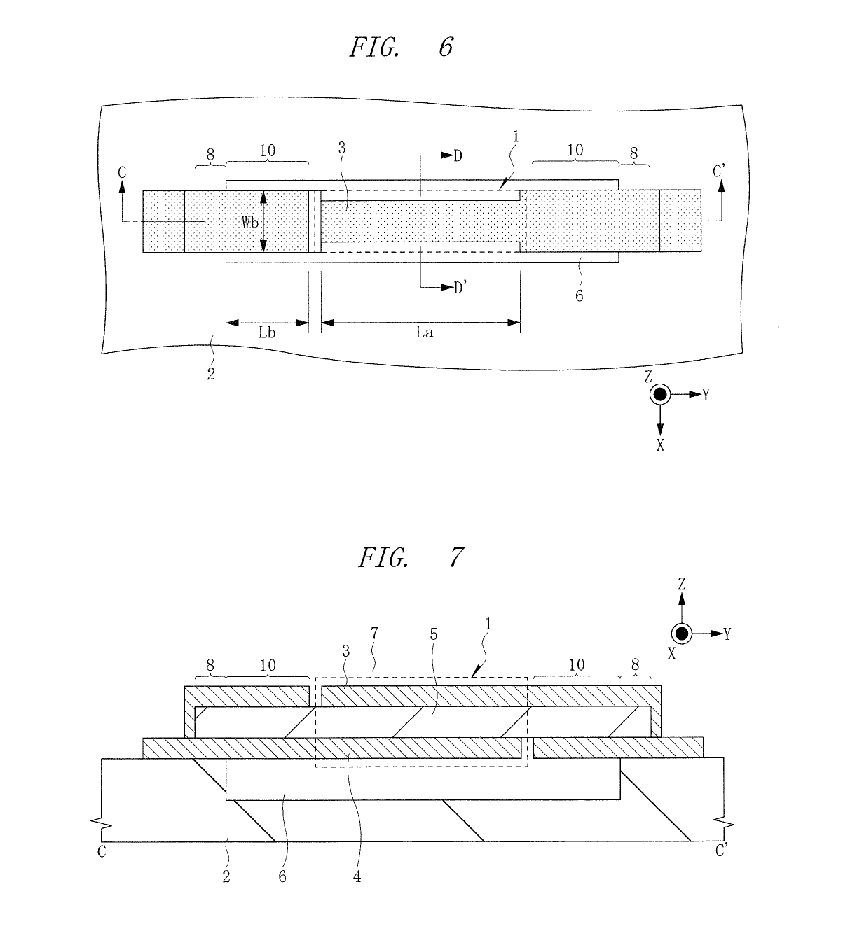

FIG. 5 is a graph showing a relation between k2 and W/h of the beam-type resonator according to the first embodiment. As the piezoelectric thin film 5, a c-axis oriented aluminum nitride film is used. Here, for ease of understanding, the thicknesses of the upper metal film 3 and the lower metal film 4 are disregarded, and the length L is assumed to be sufficiently longer than the thickness h (infinite length). The fixing surface 9 is also assumed to be at infinite distance, but since the vibrating part 1 is in contact with the fixing surface 9, vibrations in the Y axis direction are not generated. Also, k2 is calculated by using a definition equation in the case of longitudinal vibration from a series resonance frequency fs and a parallel resonance frequency fp, that is:

k2=π/2×(fs/fp)×tan {π/2×(fp−fs)/fp}

For comparison, k2 in the case of vibrations only in the Z axis direction (k2 of FBAR) and k2 in the case of vibrations only in the X axis direction (k2 of width vibration) are shown.

It can be understood from FIG. 5 that k2 larger than that of FBAR can be obtained by setting W/h to be smaller than 1.05. Also, k2 larger than that of width vibration can be obtained in all W/h. It can be thought from FIG. 5 that, for example, a range from 0.1 to 1.05 is suitable for W/h (as a matter of course, this range is not meant to be restrictive depending on other conditions). Also, as a range suitable for mass production, 0.2 to 0.9 is conceivable, and further it can be thought that a range from 0.3 to 0.88 or the like around 0.6 as a center value is most suitable.

As described above, according to the first embodiment, by setting a ratio between the width Wa and the thickness ha of the vibrating part 1 (Wa/ha) to be smaller than 1.05, a beam-type resonator having k2 larger than that of FBAR can be provided.

### Second Embodiment

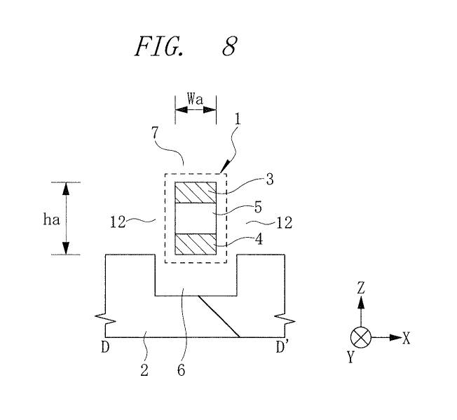

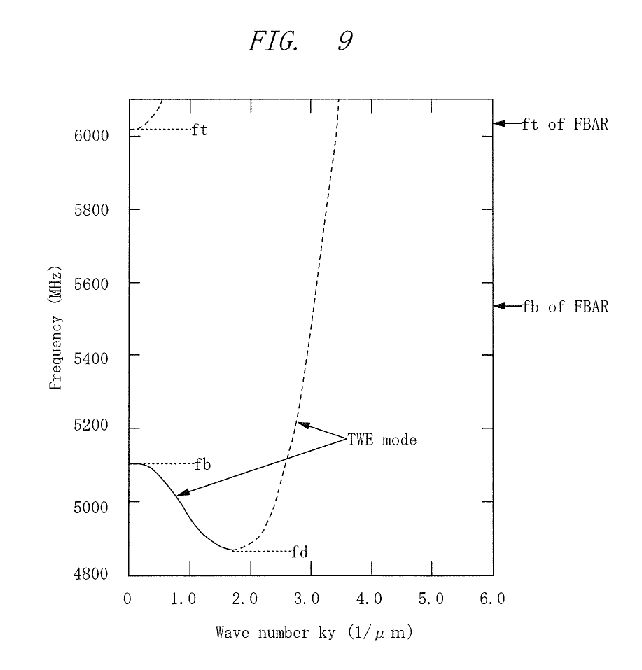

A beam-type resonator according to the second embodiment will be described with reference to FIG. 6 to FIG. 8. FIG. 6 is a schematic top view of the beam-type resonator, FIG. 7 is a schematic cross-sectional view of the beam-type resonator taken along a C-C′ line of FIG. 6, and FIG. 8 is a schematic cross-sectional view of the beam-type resonator taken along a D-D′ line of FIG. 6.

As shown in FIG. 6 to FIG. 8, the beam-type resonator is formed on an insulating substrate 2. A vibrating part 1 of this beam-type resonator has the same shape as the vibrating part 1 of the first embodiment described above. Note that, while the width of a piezoelectric thin film 5 of the vibrating part 1 and the width of an upper metal film 3 are made to coincide with each other in the second embodiment, this does not influence the effect of the present invention.

An acoustic insulating part 10 is physically connected between the vibrating part 1 and a fixing part 8. It is not always necessary to directly connect the vibrating part 1 and the acoustic insulating part 10 or the acoustic insulating part 10 and the fixing part 8, and they may be physically connected via another structure.

The acoustic insulating part 10 is made up of the upper metal film 3, the piezoelectric thin film 5, and a lower metal film 4. The upper metal film 3 of the acoustic insulating part 10 in a plus Y axis direction and the lower metal film 4 of the acoustic insulating part 10 in a minus Y axis direction each also function as an electric lead-out line. Furthermore, a width Wb of the acoustic insulating part 10 in an X axis direction (fourth dimension) is set to, for example, 0.8 μm, and a length Lb in a Y axis direction is set to, for example, 10 μm.

The natural resonance frequency of the acoustic insulating part 10 is set to be lower than the natural resonance frequency of the vibrating part 1. Here, the natural resonance frequency of the vibrating part 1 is a series resonance frequency of the vibrating part 1 in the TWE mode. Also, the natural resonance frequency of the acoustic insulating part 10 is a resonance frequency when the acoustic insulating part 10 vibrates in the TWE mode. In the case where electrodes are present on upper and lower surfaces, if the electrodes on the upper and lower surfaces are electrically short-circuited, the frequency coincides with a series resonance frequency when an alternating voltage is applied to the electrodes on the upper and lower surfaces, and if the electrodes on the upper and lower surfaces are electrically opened, the frequency coincides with a parallel resonance frequency when an alternating voltage is applied to the electrodes on the upper and lower surfaces. Also, in the case where no electrode is present on one or both of the upper and lower surfaces, an electrode having a thickness of zero is virtually assumed on the surface where no electrode is present, and the frequency coincides with the parallel resonance frequency when an alternating voltage is applied to the electrodes on the upper and lower surfaces. In the second embodiment, the upper and lower surfaces each have an electrode, and the electrodes on the upper and lower surfaces are electrically short-circuited.

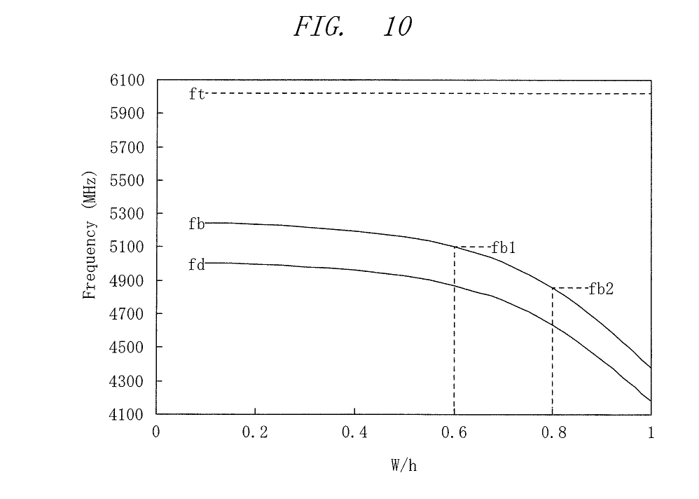

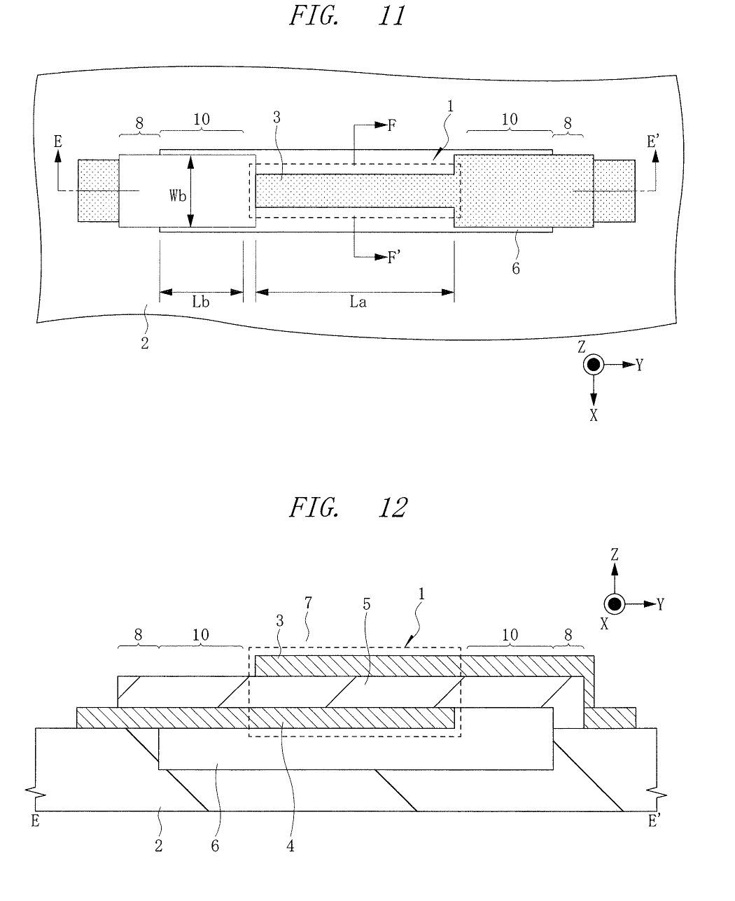

FIG. 9 and FIG. 10 are graphs for describing the behaviors of the vibrating part and the acoustic insulating part in the TWE mode according to the second embodiment. FIG. 9 is a graph showing a dispersion curve (ky real number plane, ky: wave number along y axis direction) in the TWE mode of the beam-type resonator in which a width W, a length L, and a thickness h of the vibrating part or the acoustic insulating part are set to 0.6 μm, 100 μm, and 1 μm. FIG. 10 is a graph showing dependency of frequencies fd, fb, and ft on the width W shown in FIG. 9.

As shown in FIG. 9, when ky is decreased, the frequency in the TWE mode is also decreased and is then increased again after it becomes minimum. At a frequency of 5100 MHz, ky becomes 0, and the mode is then changed via a complex plane of ky to another mode of a frequency of about 6020 MHz, and the frequency appears again on the real number plane of ky. Since the TWE mode in an area where ky is large (indicated by a broken line in the drawing) has weak coupling to an excitation electrode, in a real device, excitation or vibration occurs in the TWE mode only in a range from the frequency fd to the frequency fb indicated by a solid line in FIG. 9. More specifically, the range from the frequency fd to the frequency fb serves as an acoustic propagation frequency band. On the other hand, in the range between the frequency fb and the frequency ft, excitation, vibration, or propagation does not occur in any mode. Therefore, the frequency range between the frequency fb and the frequency ft serves as an acoustic insulating frequency band.

Since coupling to the excitation electrode becomes strong when ky is small, if it is desired to obtain strong single resonance characteristics, a TWE mode with ky of 0 or almost 0 is used. The resonance frequency at this time approximately coincides with the frequency fb or is shifted from the frequency fb slightly to a low frequency side. The shift amount depends on the length L, but when L/h>>1, since a gradient is zero when ky in the TWE mode is 0, this amount is negligible. In the second embodiment, since L/h>>1, the resonance frequency approximately coincides with the frequency fb. However, when the length L is several times the thickness h or when a high-order inharmonic-type TWE mode is used, the resonance frequency is shifted from the frequency fb to a low frequency side and always becomes a frequency between the frequency fd and the frequency fb.

Focusing on the fact that the TWE mode has vibration components in the X axis direction unlike the conventional FBAR, the inventors of the present invention have studied in detail a method of efficiently trapping vibration energy in the vibrating part 1 and a method of physically or electrically connecting the fixing part 8 and the vibrating part 1. As a result, it is found that, when W/h is changed, the frequency fb is changed correspondingly in the TWE mode. With the use of this, it is also found that, by disposing the acoustic insulating part 10 having the width Wb larger than that of the vibrating part 1 between the vibrating part 1 and the fixing part 8, vibration energy can be trapped in the vibrating part 1 and physically strong connection to the insulating substrate 2 can be achieved. The effect of the acoustic insulating part 10 will be described in detail below.

FIG. 10 is a graph showing dependency of the frequencies fb and ft on the width W according to the second embodiment. When the width W is increased, the frequency ft hardly changes, but the frequency fb moves to a low frequency side. Since a frequency between the frequency fb and the frequency ft functions as an acoustic insulating frequency, when the width W is increased, an acoustic insulating frequency band is widened.

In the second embodiment, the vibrating part 1 vibrates at a vibration frequency fb1. Since the acoustic insulating frequency of the acoustic insulating part 10 is a frequency between a vibration frequency fb2 and the frequency ft and fb2<fb1<ft, the vibration energy of the vibrating part 1 does not enter the acoustic insulating part 10. Since the frequency ft does not have dependency on the width W, by making the width Wb of the acoustic insulating part 10 larger than the width Wa of the vibrating part 1, fb2<fb1<ft can always be kept. Therefore, the acoustic insulating part 10 shows a function of acoustically insulating the vibrating part 1 and the fixing part 8.

The vibrating part 1 is surrounded by acoustic wave reflectors 6, 7, and 12 in the z axis direction and the X axis direction and by the acoustic insulating part 10 in the Y axis direction. Therefore, in the second embodiment, acoustic energy can be trapped in the vibrating part 1.

As described above, according to the second embodiment, in the beam-type resonator, the acoustic insulating part 10 is placed between the vibrating part 1 and the fixing part 8, and the width Wb of the acoustic insulating part 10 is set to have a value larger than that of the width Wa of the vibrating part 1. By this means, the acoustic energy can be trapped in the resonating part.

### Third Embodiment

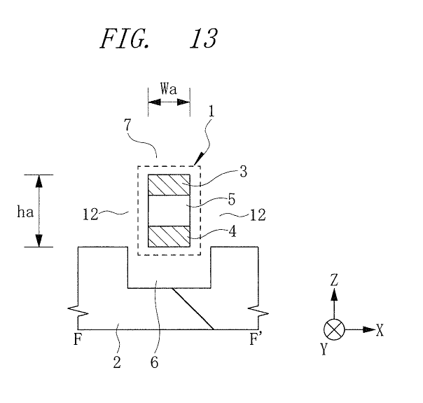

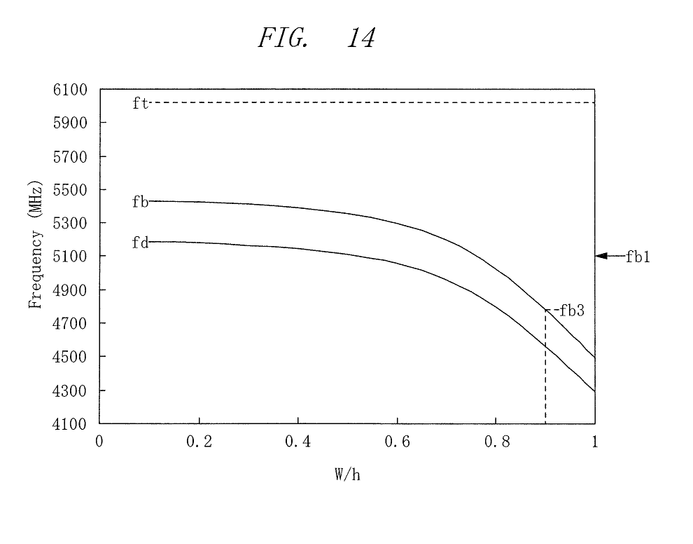

A beam-type resonator according to the third embodiment will be described with reference to FIG. 11 to FIG. 13. FIG. 11 is a schematic top view of the beam-type resonator, FIG. 12 is a schematic cross-sectional view of the beam-type resonator taken along an E-E′ line of FIG. 11, and FIG. 13 is a schematic cross-sectional view of the beam-type resonator taken along an F-F′ line of FIG. 11.

As shown in FIG. 11 to FIG. 13, the beam-type resonator according to the third embodiment has the same shape as the beam-type resonator according to the second embodiment described above except a fixing part 8 and an acoustic insulating part 10. The acoustic insulating part 10 is made up of an upper metal film 3 and a piezoelectric thin film 5 or the piezoelectric thin film 5 and the lower metal film 4. The fixing part 8 is made up of the upper metal film 3 and the piezoelectric thin film 5 or the piezoelectric thin film 5 and the lower metal film 4. The upper metal film 3 of the acoustic insulating part 10 in a plus Y axis direction and the lower metal film 4 of the acoustic insulating part 10 in a minus Y axis direction each also function as an electrical lead-out line. Also, a width Wb of the acoustic insulating part 10 in an X axis direction is set to, for example, 0.9 μm, and an Lb in a Y axis direction is set to, for example, 10 μm.

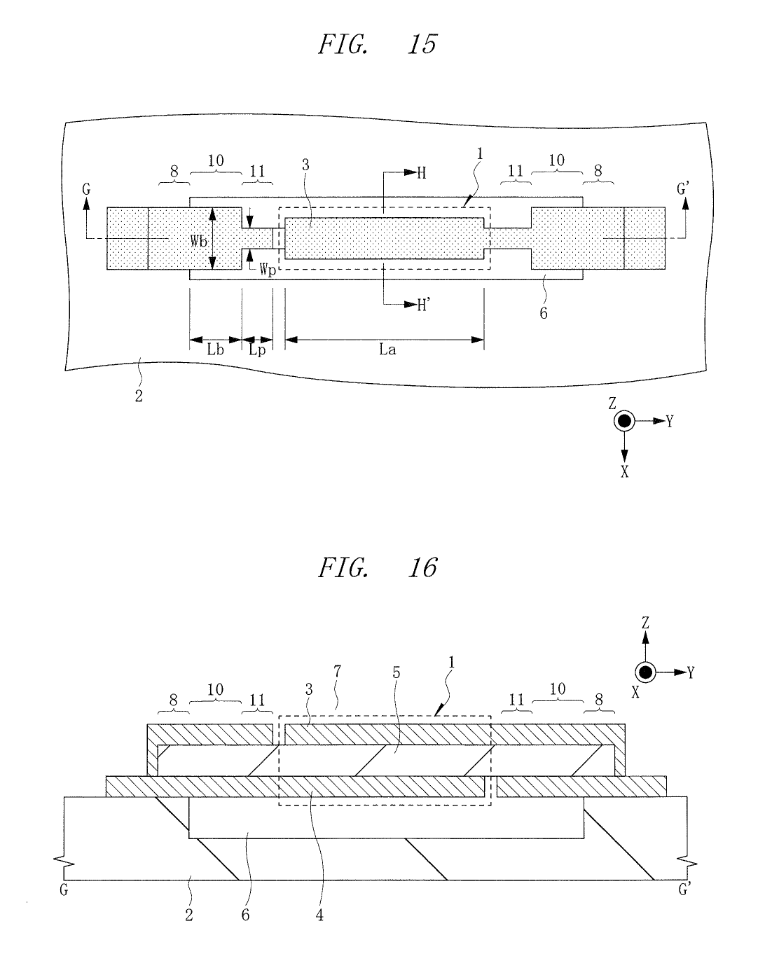

FIG. 14 is a graph showing dependency of the frequencies fb and ft of the acoustic insulating part 10 on the width W according to the third embodiment. Since no upper metal film 3 or lower metal film 4 is provided, a vibration frequency fb3 is shifted to a high frequency side more than the vibration frequency fb1 of the second embodiment described above. For ease of understanding, the vibration frequency fb1 of the vibrating part 1 is shown in FIG. 14.

In the third embodiment, the vibrating part 1 vibrates at the vibration frequency fb1. Since the acoustic insulating frequency of the acoustic insulating part 10 is a frequency between the vibration frequency fb3 and the frequency ft and fb3<fb1<ft, the vibration energy of the vibrating part 1 does not enter the acoustic insulating part 10. Therefore, the acoustic insulating part 10 shows a function of acoustically insulating the vibrating part 1 and the fixing part 8.

The vibrating part 1 is surrounded by acoustic wave reflectors 6, 7, and 12 in the Z axis direction and the X axis direction and by the acoustic insulating part 10 in the Y axis direction. Therefore, also in the third embodiment, acoustic energy can be trapped in the vibrating part 1.

As described above, according to the third embodiment, like in the second embodiment described above, in the beam-type resonator, the acoustic insulating part 10 is placed between the vibrating part 1 and the fixing part 8, and the width Wb of the acoustic insulating part 10 is set to have a value larger than that of the width Wa of the vibrating part 1. By this means, the acoustic energy can be trapped in the resonating part.

### Fourth Embodiment

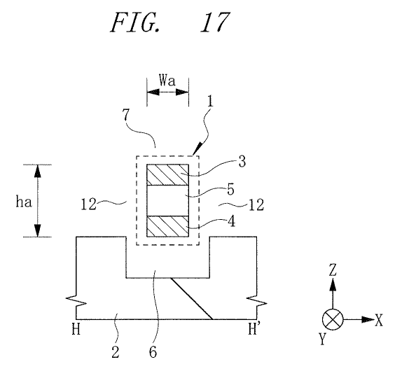

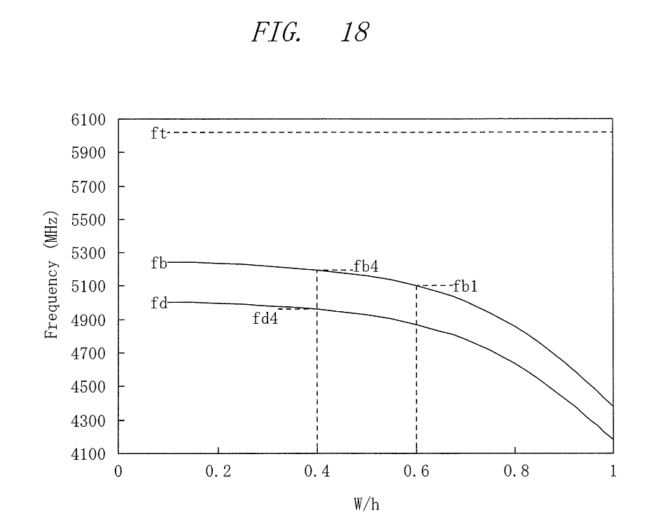

A beam-type resonator according to the fourth embodiment will be described with reference to FIG. 15 to FIG. 17. FIG. 15 is a schematic top view of the beam-type resonator, FIG. 16 is a schematic cross-sectional view of the beam-type resonator taken along a G-G′ line of FIG. 15, and FIG. 17 is a schematic cross-sectional view of the beam-type resonator taken along an H-H′ line of FIG. 15.

As shown in FIG. 15 to FIG. 17, the beam-type resonator is formed on an insulating substrate 2. A vibrating part 1 of this beam-type resonator has the same shape as the vibrating part 1 according to the second embodiment described above. Also, an acoustic insulating part 10 has the same shape as the acoustic insulating part 10 according to the second embodiment described above.

A phase rotating part 11 is physically connected between the vibrating part 1 and the acoustic insulating part 10. It is not always necessary to directly connect the vibrating part 1 and the phase rotating part 11 or the phase rotating part 11 and the acoustic insulating part 10, and they may be physically connected via another structure.

The phase rotating part 11 is made up of an upper metal film 3, a piezoelectric thin film 5, and a lower metal film 4. The upper metal film 3 of the phase rotating part 11 in a plus Y axis direction and the lower metal film 4 of the phase rotating part 11 in a minus Y axis direction each also function as an electric lead-out line. Also, a width Wp of the phase rotating part 11 in an X axis direction (fifth dimension) is set to, for example, 0.4 μm, and a length Lp in a Y axis direction is set to, for example, 1.2 μm.

The natural resonance frequency of the phase rotating part 11 is set to be larger than one time and smaller than 1.05 times the natural resonance frequency of the vibrating part 1. Here, the natural resonance frequency of the phase rotating part 11 is a resonance frequency when the phase rotating part 11 vibrates in the TWE mode. In the case where electrodes are present on upper and lower surfaces, if the electrodes on the upper and lower surfaces are electrically short-circuited, the frequency coincides with a series resonance frequency when an alternating voltage is applied to the electrodes on the upper and lower surfaces, and if the electrodes on the upper and lower surfaces are electrically opened, the frequency coincides with a parallel resonance frequency when an alternating voltage is applied to the electrodes on the upper and lower surfaces. Also, in the case where no electrode is present on one or both of the upper and lower surfaces, an electrode having a thickness of zero is virtually assumed on the surface where no electrode is present, and the frequency coincides with the parallel resonance frequency when an alternating voltage is applied to the electrodes on the upper and lower surfaces. In the fourth embodiment, the upper and lower surfaces each have an electrode, and the electrodes on the upper and lower surfaces are electrically short-circuited.

Focusing on the fact that the TWE mode has vibration components in the X axis direction unlike the conventional FBAR, the inventors of the present invention have studied in detail a method of changing the vibration mode of the vibrating part 1 to a piston mode and a method of physically connecting the acoustic insulating part 10 and the vibrating part 1. As a result, it is found that, when the width W is changed, the frequency fd is changed correspondingly in the TWE mode. It is also found that a ratio of change of the frequency fd is approximately equal to a ratio of change of the frequency fb. With the use of this, it is found that, by disposing the phase rotating part 11 having the width Wp different from that of the vibrating part 1 between the vibrating part 1 and the acoustic insulating part 10, the vibration mode of the vibrating part 1 can be changed to the piston mode and physically strong connection to the insulating substrate 2 can be achieved. The effect of the phase rotating part 11 will be described in detail below.

FIG. 18 is a drawing that shows dependency of the frequencies fd and fb of the phase rotating part 11 on the width W according to the fourth embodiment. For ease of understanding, the vibration frequency fb1 of the vibrating part 1 is shown in FIG. 18.

In the fourth embodiment, the vibrating part 1 vibrates at the vibration frequency fb1. Since the acoustic propagation frequency of the phase rotating part 11 is a frequency between a vibration frequency fd4 and a vibration frequency fb4 and the vibration frequency fd4 is approximately 0.95 times the vibration frequency fb4 in the beam-type resonator. In the fourth embodiment, by making the width Wp of the phase rotating part 11 smaller than the width Wa of the vibrating part 1, fd4<fb1<fb4 can be achieved. Since fd4<fb1<fb4, the acoustic wave of the vibrating part 1 enters the phase rotating part 11 to propagate to the acoustic insulating part 10. However, since fb2<fb1<ft, the acoustic wave of the phase rotating part 11 is reflected by the acoustic insulating part 10, propagates again through the phase rotating part 11, and then returns to the vibrating part 1. Therefore, the phase rotating part 11 shows a function of controlling the phases of acoustic waves output from and returning to the vibrating part 1.

In the reflection at the acoustic insulating part 10, the phase of the acoustic wave is rotated by 180 degrees. Therefore, by rotating the phase of the acoustic wave by 90 degrees (180 degrees for to-and-fro) in the phase rotating part 11, the vibration mode of the vibrating part 1 can be changed to the piston mode.

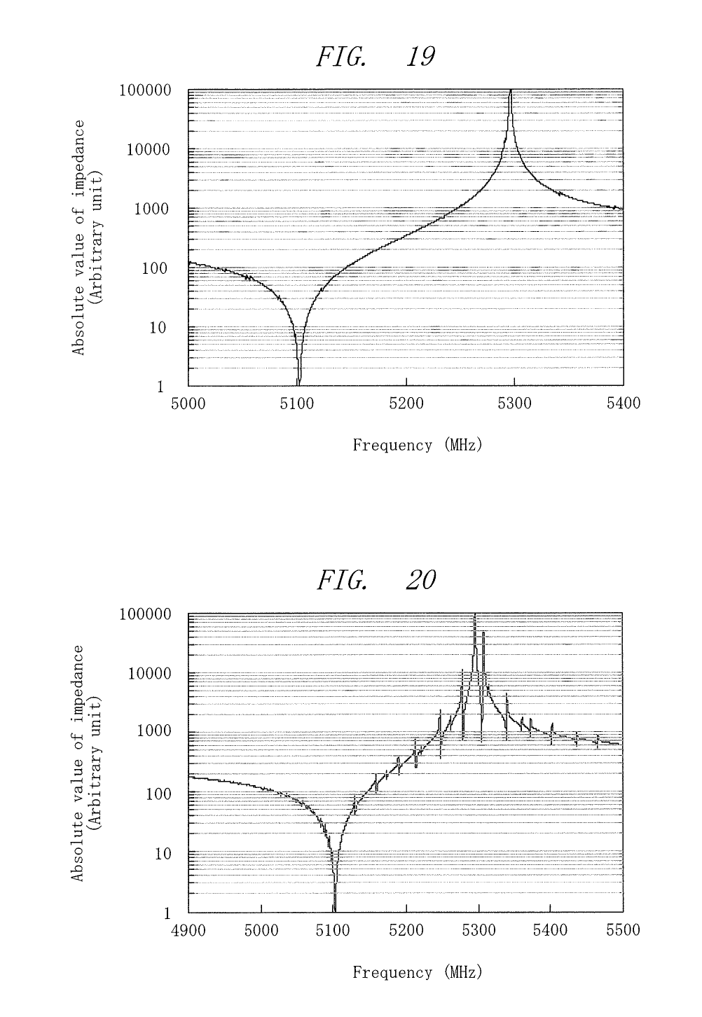

FIG. 19 and FIG. 20 are graphs showing the effect of the phase rotating part 11 according to the fourth embodiment. FIG. 19 is a graph showing impedance characteristics of the beam-type resonator according to the fourth embodiment. FIG. 20 is a graph showing impedance characteristics of the beam-type resonator in which the width Wp of the phase rotating part 11 coincides with the width Wa of the vibrating part 1 for comparison. In the fourth embodiment, since the vibration mode of the vibrating part 1 is a piston mode, spurious excitation can be suppressed.

As described above, according to the fourth embodiment, in the beam-type resonator, the phase rotating part 11 is placed between the vibrating part 1 and the acoustic insulating part 10, the width Wp of the phase rotating part 11 is set to have a value different from the width Wa of the vibrating part 1, and the resonance frequency of the phase rotating part 11 is set to be higher than the resonance frequency of the vibrating part 1. By this means, a spurious-free beam-type resonator can be provided.

### Fifth Embodiment

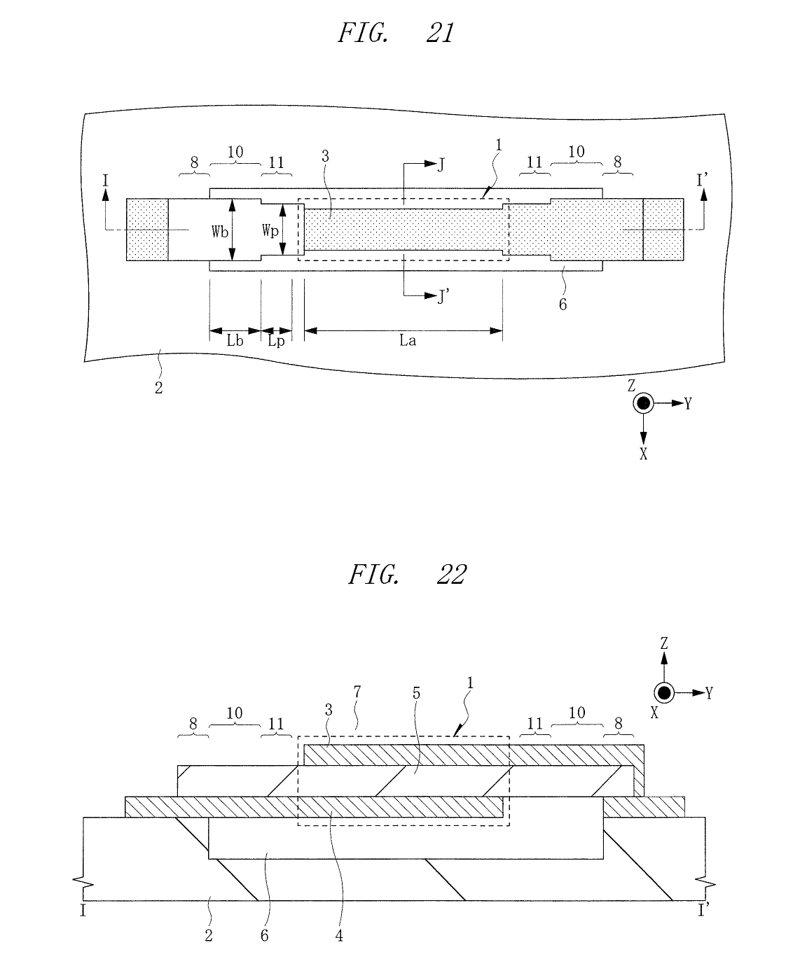

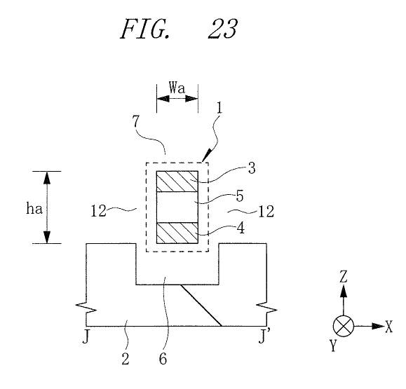

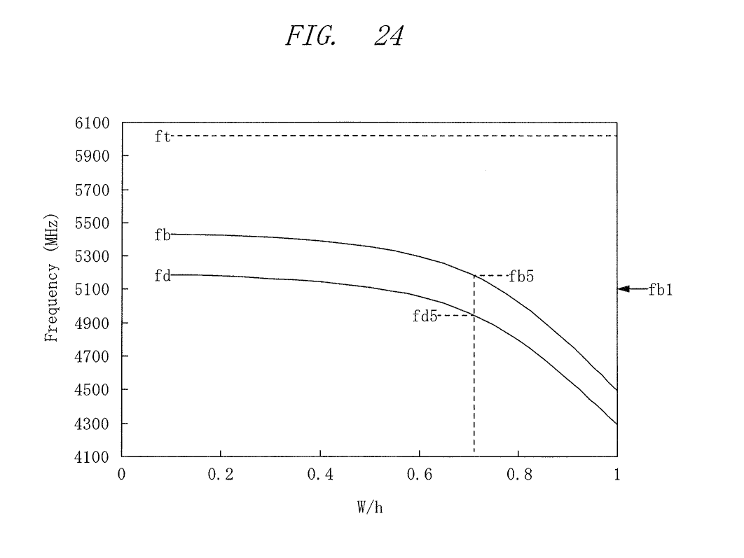

A beam-type resonator according to the fifth embodiment will be described with reference to FIG. 21 to FIG. 23. FIG. 21 is a schematic top view of the beam-type resonator, FIG. 22 is a schematic cross-sectional view of the beam-type resonator taken along an I-I′ line of FIG. 21, and FIG. 23 is a schematic cross-sectional view of the beam-type resonator taken along a J-J′ line of FIG. 21.

As shown in FIG. 21 to FIG. 23, the beam-type resonator according to the fifth embodiment has the same shape as the beam-type resonator according to the fourth embodiment described above except a phase rotating part 11. The phase rotating part 11 is made up of an upper metal film 3 and a piezoelectric thin film 5 or the piezoelectric thin film 5 and a lower metal film 4. The upper metal film 3 of the phase rotating part 11 in a plus Y axis direction and the lower metal film 4 of the phase rotating part 11 in a minus Y axis direction each also function as an electric lead-out line. Also, a width Wp of the phase rotating part 11 in an X axis direction is set to, for example, 0.7 μm, and an Lp in a Y axis direction is set to, for example, 1.0 μm.

FIG. 24 is a graph showing dependency of frequencies fd and fb of the phase rotating part 11 on the width W according to the fifth embodiment. Since no upper metal film 3 or lower metal film 4 is provided, a vibration frequency fb5 is shifted to a high frequency side more than the vibration frequency fb4 of the fourth embodiment described above. For ease of understanding, a vibration frequency fb1 of the vibrating part 1 is shown in FIG. 24. The natural resonance frequency of the phase rotating part 11 is set to be larger than one time and smaller than 1.05 times the natural resonance frequency of the vibrating part 1.

In the fifth embodiment, the vibrating part 1 vibrates at the vibration frequency fb1. The acoustic propagation frequency of the phase rotating part 11 is a frequency between a vibration frequency fd5 and the vibration frequency fb5, and the vibration frequency fd5 is approximately 0.95 times the vibration frequency fb5 in the beam-type resonator. Since fd5<fb1<fb5, the same effect as that of the fourth embodiment described above can be achieved, that is, the vibration mode of the vibrating part 1 can be changed to the piston mode. In the fifth embodiment, since the vibration mode of the vibrating part 1 is the piston mode, spurious excitation can be suppressed.

As described above, according to the fifth embodiment, in the beam-type resonator, the phase rotating part 11 is placed between the vibrating part 1 and the acoustic insulating part 10, the width Wa of the vibrating part 1 and the width Wp of the phase rotating part 11 are set to have different values, and the resonance frequency of the phase rotating part 11 is set to be higher than the resonance frequency of the vibrating part 1 like in the fourth embodiment. By this means, a spurious-free beam-type resonator can be provided.

### Sixth Embodiment

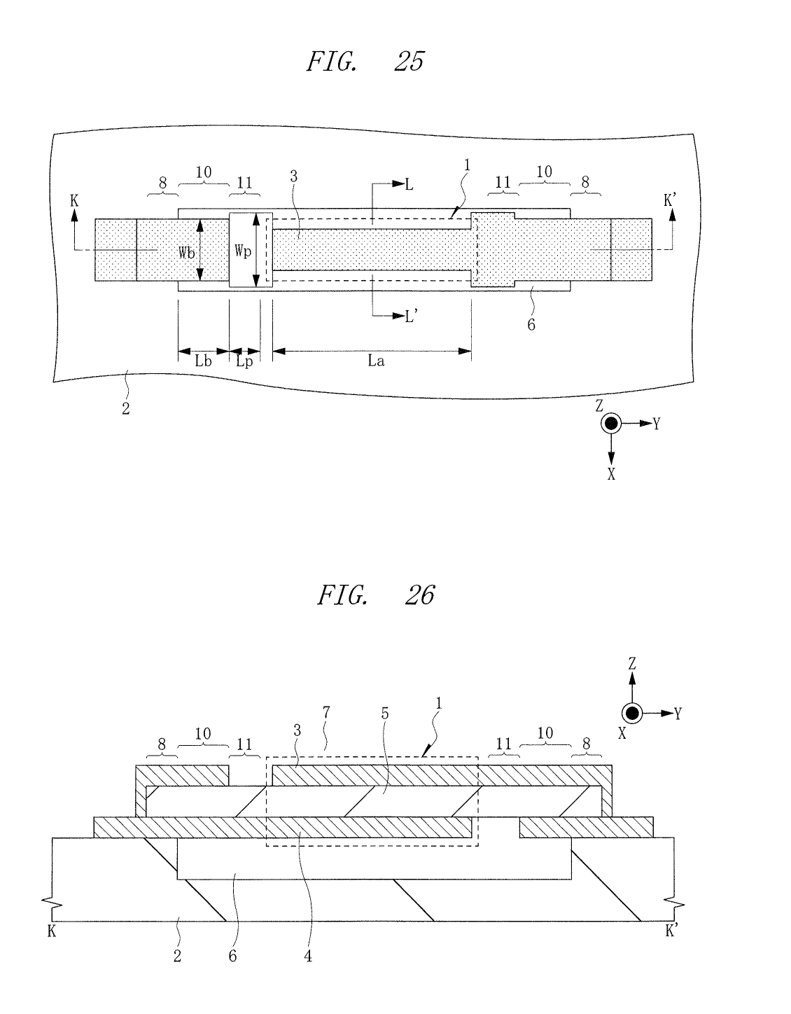

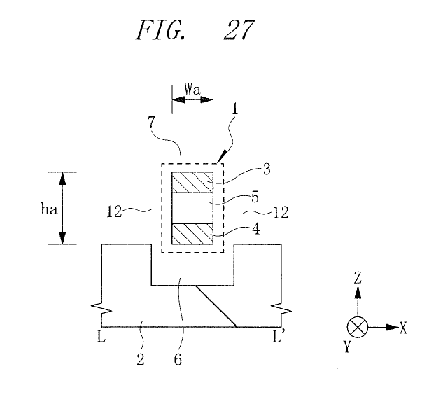

A beam-type resonator according to the sixth embodiment will be described with reference to FIG. 25 to FIG. 27. FIG. 25 is a schematic top view of the beam-type resonator, FIG. 26 is a schematic cross-sectional view of the beam-type resonator taken along a K-K′ line of FIG. 25, and FIG. 27 is a schematic cross-sectional view of the beam-type resonator taken along an L-L′ line of FIG. 25.

As shown in FIG. 25 to FIG. 27, the beam-type resonator is formed on an insulating substrate 2. The beam-type resonator is made up of a vibrating part 1, a phase rotating part 11, an acoustic insulating part 10, and a fixing part 8. The phase rotating part 11 is physically connected between the vibrating part 1 and the acoustic insulating part 10. The fixing part 8 is physically connected between the acoustic insulating part 10 and the insulating substrate 2.

The vibrating part 1 is made up of an upper metal film 3, a piezoelectric thin film 5, and a lower metal film 4. The piezoelectric thin film 5 is interposed between the upper metal film 3 and the lower metal film 4. The upper metal film 3 and the lower metal film 4 are formed of a thin film mainly made of aluminum having a thickness of, for example, 1 μm. The piezoelectric thin film 5 is formed of a thin film mainly made of C-axis oriented aluminum nitride having a thickness of, for example, 1 μm. The C axis is oriented in a direction perpendicular to the insulating substrate 2. The vibrating part 1 has a width Wa of, for example, 0.6 μm, and a length La of, for example, 100 μm. The upper metal film 3, the piezoelectric thin film 5, and the lower metal film 4 have the same width.

The phase rotating part 11 is made up of the piezoelectric thin film 5 and the lower metal film 4 or the upper metal film 3 and the piezoelectric thin film 5. The upper metal film 3 and the lower metal film 4 are formed of a thin film mainly made of aluminum having a thickness of, for example, 0.1 μm. The piezoelectric thin film 5 is formed of a thin film made of C-axis oriented aluminum nitride having a thickness of, for example, 1 μm. The C axis is oriented in a direction perpendicular to the insulating substrate 2. The phase rotating part 11 has a width Wp of, for example, 0.96 μm, and a length Lp of, for example, 1.6 μm. The piezoelectric thin film 5 and the lower metal film 4 have the same width.

The acoustic insulating part 10 is made up of the upper metal film 3, the piezoelectric thin film 5, and the lower metal film 4. The piezoelectric thin film 5 is interposed between the upper metal film 3 and the lower metal film 4. The upper metal film 3 and the lower metal film 4 are each formed of a thin film mainly made of aluminum having a thickness of, for example, 0.1 μm. The piezoelectric thin film 5 is formed of a thin film mainly made of C-axis oriented aluminum nitride having a thickness of, for example, 1 μm. The C axis is oriented in a direction perpendicular to the insulating substrate 2. The acoustic insulating part 10 has a width Wb of, for example, 0.8 μm, and a length Lb of, for example, 10 μm. The upper metal film 3, the piezoelectric thin film 5, and the lower metal film 4 have the same width. The upper metal film 3 and the lower metal film 4 on each of two acoustic insulating parts 10 are electrically connected at portions different from the acoustic insulating parts 10 so as to have equal electric potential.

The fixing part 8 is made up of the upper metal film 3, the piezoelectric thin film 5, and the lower metal film 4. The piezoelectric thin film 5 is interposed between the upper metal film 3 and the lower metal film 4. The upper metal film 3 and the lower metal film 4 are each formed of a thin film mainly made of aluminum having a thickness of, for example, 0.1 μm. The piezoelectric thin film 5 is formed of a thin film mainly made of C-axis oriented aluminum nitride having a thickness of, for example, 1 μm. The C axis is oriented in a direction perpendicular to the insulating substrate 2. Two fixing parts 8 are electrically connected so that the upper metal film 3 and the lower metal film 4 have equal electric potential.

The insulating substrate 2 is made up of a single-crystal silicon substrate and a silicon oxide film having a thickness of 1 μm formed on the surface thereof. By forming a silicon oxide film on the surface, the single-crystal silicon substrate electrically functions as an insulating substrate.

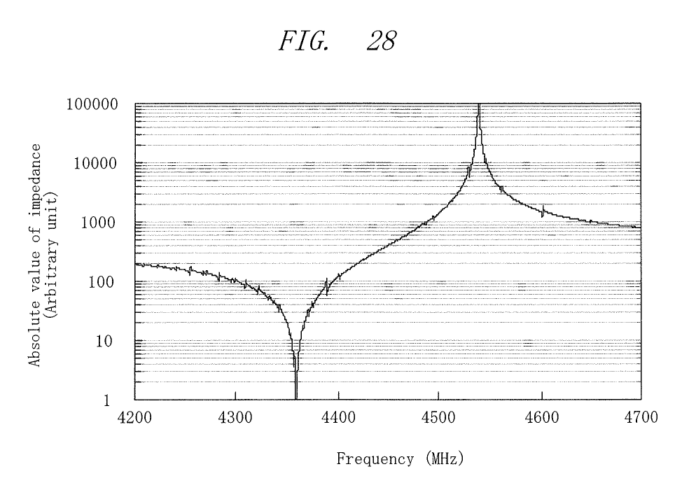

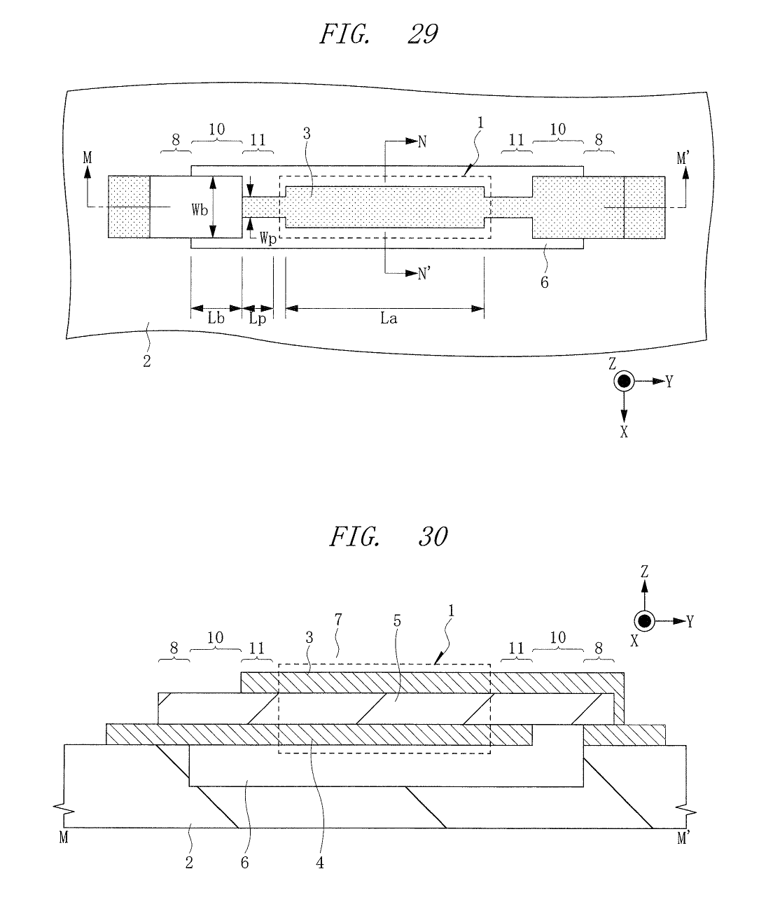

FIG. 28 is a graph showing impedance characteristics of the beam-type resonator according to the sixth embodiment. Since aluminum is used as an electrode material, k2 becomes 9.44%, which indicates a value further larger than the value shown in FIG. 5 described above. Also, all of the vibrating part 1, the phase rotating part 11, the acoustic insulating part 10, and the fixing part 8 are made up of the upper metal film 3, the piezoelectric thin film 5, and the lower metal film 4 having the same film thickness. Accordingly, the resonator can be formed with three film-forming processes, and the trapping of energy and excitation in the piston mode can be achieved with the number of processes smaller than that of the known technology disclosed in, for example, Patent Document 2. As a result, a low-loss, spurious-free beam-type resonator can be provided at low cost.

### Seventh Embodiment

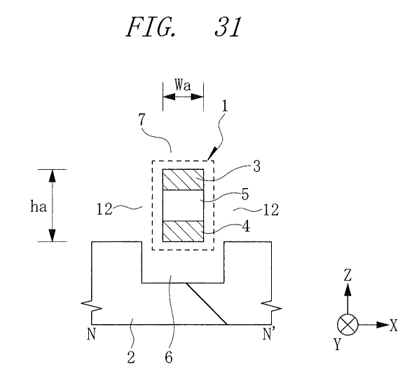

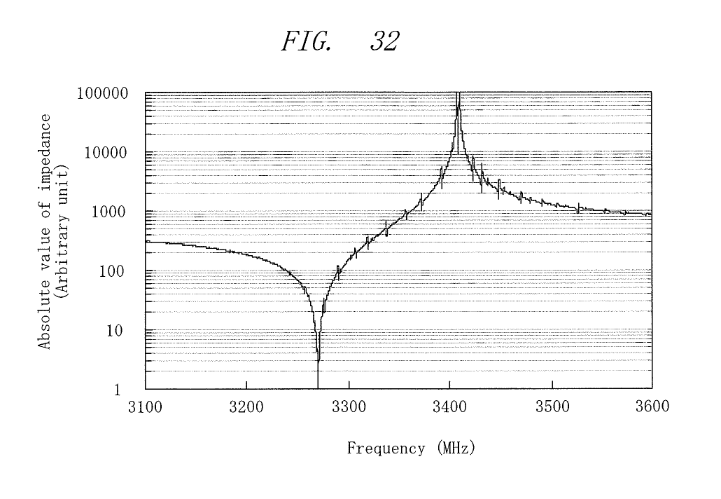

A beam-type resonator according to the seventh embodiment will be described with reference to FIG. 29 to FIG. 31. FIG. 29 is a schematic top view of the beam-type resonator, FIG. 30 is a schematic cross-sectional view of the beam-type resonator taken along an M-M′ line of FIG. 29, and FIG. 31 is a schematic cross-sectional view of the beam-type resonator taken along an N-N′ line of FIG. 29.

As shown in FIG. 29 to FIG. 31, the beam-type resonator is formed on an insulating substrate 2. The beam-type resonator is made up of a vibrating part 1, a phase rotating part 11, an acoustic insulating part 10, and a fixing part 8. The phase rotating part 11 is physically connected between the vibrating part 1 and the acoustic insulating part 10. The fixing part 8 is physically connected between the acoustic insulating part 10 and the insulating substrate 2.

The vibrating part 1 is made up of an upper metal film 3, a piezoelectric thin film 5, and a lower metal film 4. The piezoelectric thin film 5 is interposed between the upper metal film 3 and the lower metal film 4. The upper metal film 3 and the lower metal film 4 are each formed of a thin film mainly made of molybdenum having a thickness of, for example, 0.1 μm. The piezoelectric thin film 5 is formed of a thin film mainly made of C-axis oriented aluminum nitride having a thickness of, for example, 1 μm. The C axis is oriented in a direction perpendicular to the insulating substrate 2. The vibrating part 1 has a width Wa of, for example, 0.6 μm, and a length La of, for example, 100 μm. The upper metal film 3, the piezoelectric thin film 5, and the lower metal film 4 have the same width.

The phase rotating part 11 is made up of the upper metal film 3, the piezoelectric thin film 5, and the lower metal film 4. The lower metal film 4 is formed of a thin film mainly made of molybdenum having a thickness of, for example, 0.1 μm. The piezoelectric thin film 5 is formed of a thin film mainly made of C-axis oriented aluminum nitride having a thickness of, for example, 1 μm. The C axis is oriented in a direction perpendicular to the insulating substrate 2. The phase rotating part 11 has a width Wp of, for example, 0.4 μm, and a length Lp of, for example, 3.5 μm. The piezoelectric thin film 5 and the lower metal film 4 have the same width.

The acoustic insulating part 10 is made up of the upper metal film 3 and the piezoelectric thin film 5 or the piezoelectric thin film 5 and the lower metal film 4. The upper metal film 3 and the lower metal film 4 are each formed of a thin film mainly made of molybdenum having a thickness of, for example, 0.1 μm. The piezoelectric thin film 5 is formed of a thin film mainly made of C-axis oriented aluminum nitride having a thickness of, for example, 1 μm. The C axis is oriented in a direction perpendicular to the insulating substrate 2. The acoustic insulating part 10 has a width Wb of, for example, 1.4 μm, and a length Lb of, for example, 10 μm. The upper metal film 3, the piezoelectric thin film 5, and the lower metal film 4 have the same width.

The fixing part 8 is made up of the upper metal film 3, the piezoelectric thin film 5, and the lower metal film 4 or the piezoelectric thin film 5 and the lower metal film 4. In the fixing part 8 on a plus Y axis direction side of FIG. 30, the piezoelectric thin film 5 is interposed between the upper metal film 3 and the lower metal film 4. The upper metal film 3 and the lower metal film 4 are each formed of a thin film mainly made of molybdenum having a thickness of 0.1 μm. The piezoelectric thin film 5 is formed of a thin film mainly made of C-axis oriented aluminum nitride having a thickness of, for example, 1 μm. The C axis is oriented in a direction perpendicular to the insulating substrate 2. In the fixing part 8 on a minus Y axis direction side of FIG. 30, the upper metal film 3 and the lower metal film 4 are electrically connected to each other so as to have equal electric potential.

The insulating substrate 2 is made up of a single-crystal silicon substrate and a silicon oxide film having a thickness of 1 μm formed on the surface thereof. By forming a silicon oxide film on the surface, the single-crystal silicon substrate electrically functions as an insulating substrate.

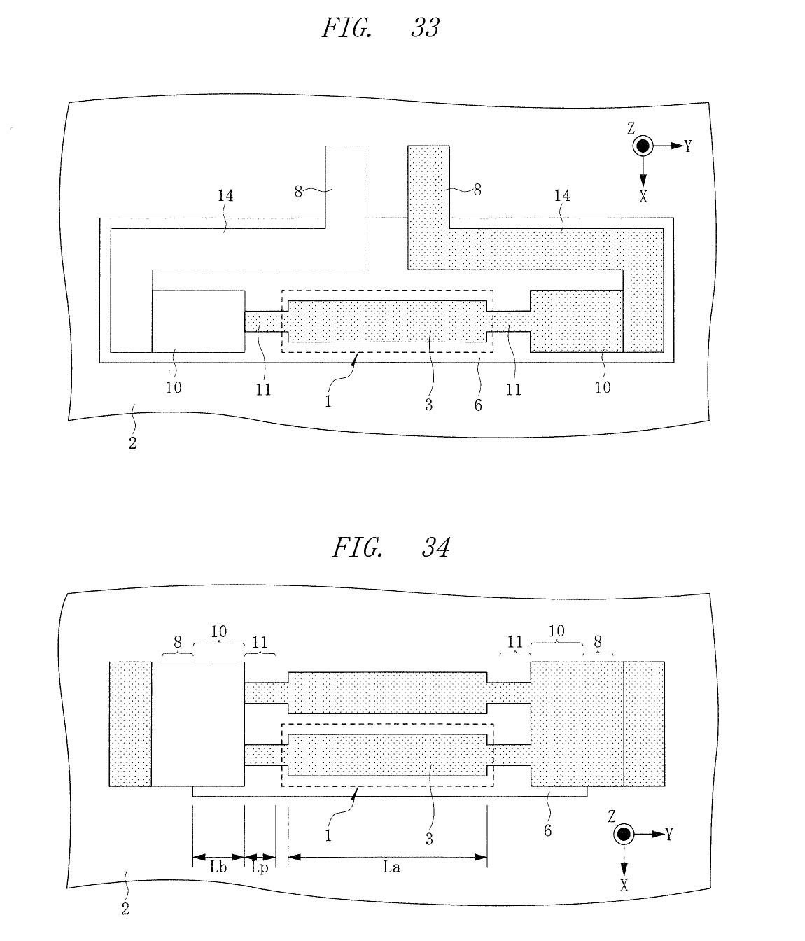

FIG. 32 is a graph showing impedance characteristics of the beam-type resonator according to the seventh embodiment. Since heavy molybdenum is used as an electrode material, k2 becomes 9.73%, which indicates a value further larger than the value shown in the sixth embodiment described above. Also, as with the sixth embodiment, all of the vibrating part 1, the phase rotating part 11, the acoustic insulating part 10, and the fixing part 8 are made up of the upper metal film 3, the piezoelectric thin film 5, and the lower metal film 4 having the same film thickness. Accordingly, the resonator can be formed with three film-forming processes, and the trapping of energy and excitation in the piston mode can be achieved with the number of processes smaller than that of the known technology disclosed in, for example, Patent Document 2. As a result, a low-loss, spurious-free beam-type resonator can be provided at low cost.

### Eighth Embodiment

A beam-type resonator according to the eighth embodiment will be described with reference to FIG. 33. The resonator according to the eighth embodiment is a modification example of the seventh embodiment described above. More specifically, the fixing part 8 is spatially positioned in a minus X axis direction of the vibrating part 1, but physically, it is indirectly connected in a plus Y axis direction and a minus Y axis direction of the vibrating part 1. Accordingly, the resonator has a function similar to that of the seventh embodiment described above.

### Ninth Embodiment

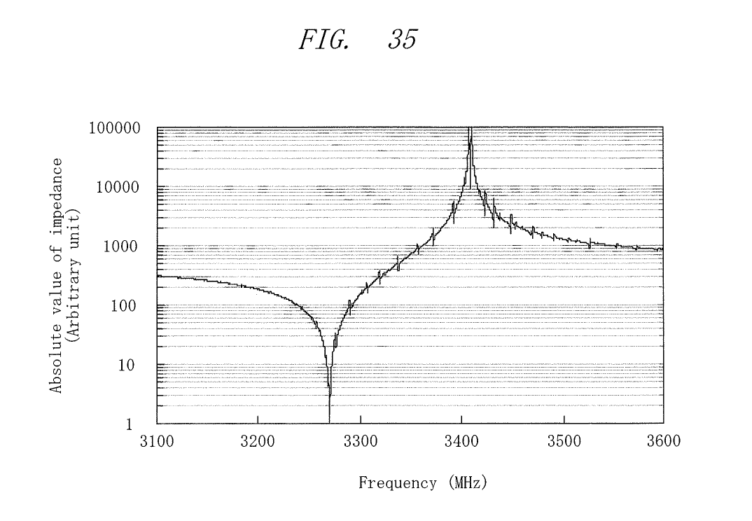

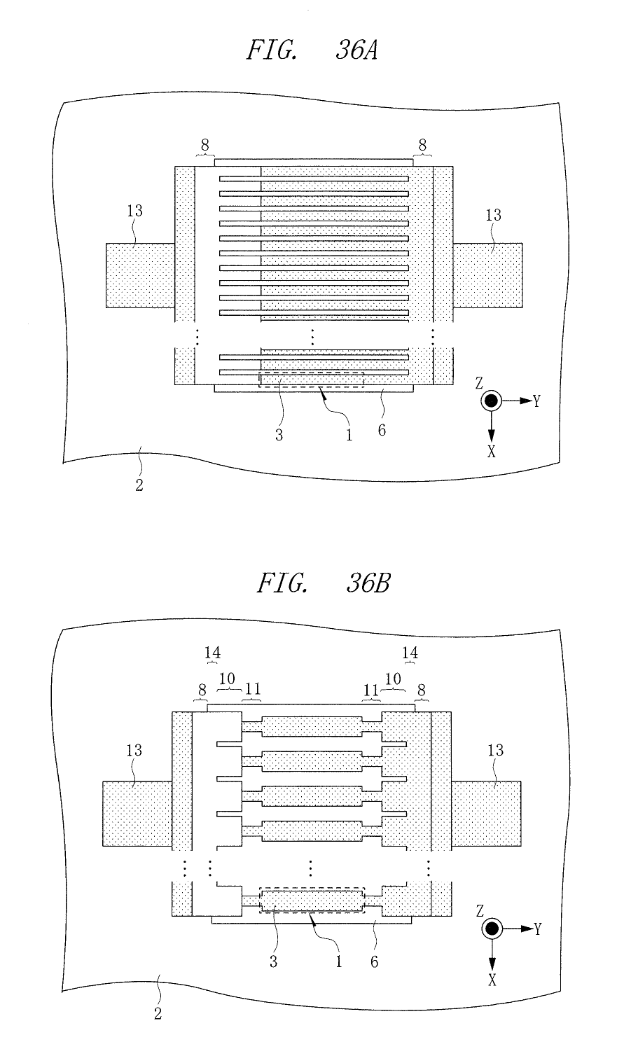

A beam-type resonator having a plurality of vibrating parts according to the ninth embodiment will be described with reference to FIG. 34 and FIG. 35. FIG. 34 is a schematic top view of the beam-type resonator, and FIG. 35 is a graph showing impedance characteristics of the beam-type resonator.

As shown in FIG. 34, two portions each formed of a vibrating part 1 and a phase rotating part 11 are connected to a common acoustic insulating part 10. The phase rotating part 11 has the same shape as the phase rotating part 11 of the seventh embodiment described above. As with the vibrating part 1 of the seventh embodiment described above, the vibrating part 1 is made up of an upper metal film 3, a piezoelectric thin film 5, and a lower metal film 4. The vibrating part 1 has a width Wa of, for example, 0.6 μm and a length La of, for example, 50 μm, and the upper metal film 3, the piezoelectric thin film 5, and the lower metal film 4 have the same width.

As with the seventh embodiment, the acoustic insulating part 10 is made up of the upper metal film 3 and the piezoelectric thin film 5 or the piezoelectric thin film 5 and the lower metal film 4. The acoustic insulating part 10 has a width Wb of, for example, 1.9 μm and a length Lb of, for example, 10 μm, and the upper metal film 3, the lower metal film 4, and the piezoelectric thin film 5 have the same width.

Also, as shown in FIG. 35, the beam-type resonator has electric characteristics similar to those of the seventh embodiment described above. Since the vibration frequencies of two vibrating parts 1 are within an insulating frequency range of the acoustic insulating part 10, the acoustic insulating part 10 achieves the same function as that of the acoustic insulating part 10 of the seventh embodiment. Even when a plurality of vibrating parts 1 are connected to one acoustic insulating part 10, the effect of the invention is not changed.

### Tenth Embodiment

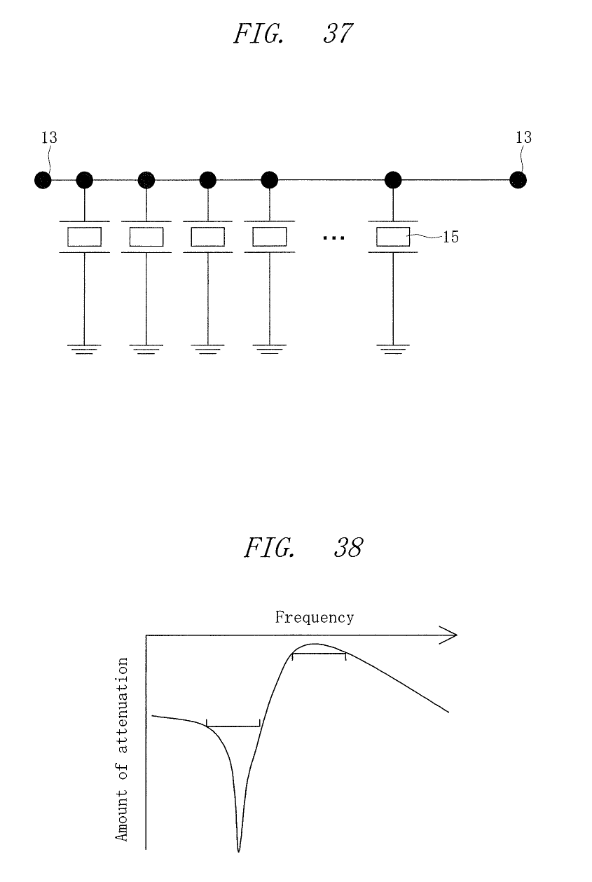

A beam-type resonator group according to the tenth embodiment will be described with reference to FIG. 36. FIG. 36A is a schematic top view of a first example of a beam-type resonator group in which many beam-type resonators shown in the first embodiment described above are connected in parallel, and FIG. 36B is a schematic top view of a second example of a beam-type resonator group in which many beam-type resonators shown in the seventh embodiment described above are connected in parallel. The beam-type resonator group in which a plurality of beam-type resonators shown in the seventh embodiment described above are connected in parallel will be described below.

As shown in FIG. 36B, a plurality of beam-type resonators are formed on one lower acoustic wave reflector 6. These beam-type resonators share one fixing part 8. With one fixing part 8, all of the beam-type resonators are electrically connected together, and are connected to a common input/output terminal 13. Also, an acoustic insulating part 10 and the fixing part 8 are physically connected to each other via a connecting part 14. Since the plurality of beam-type resonators share the lower acoustic wave reflector 6, many beam-type resonators can be disposed on a chip. Therefore, the chip can be reduced in size.

When an impedance element such as a resonator is used as a high-frequency electrical component such as a high-frequency filter or is connected to another component to form a system, it is necessary to make the characteristic impedance coincide with that of an electrical component of a connection destination. Although the characteristic impedance can be freely set among components, since electric resistance loss increases if the characteristic impedance is too low or since the voltage amplitude exceeds the power supply voltage if the characteristic impedance is too high, the characteristic impedance is generally set at 50 to 200Ω. However, by using the beam-type resonator group, the number of beam-type resonators to be connected in parallel can be adjusted, and the arbitrary characteristic impedance can be achieved.

As described above, according to the tenth embodiment, by disposing a plurality of beam-type resonators on one lower acoustic wave reflector 6, a small-sized high-frequency filter capable of arbitrary setting characteristic impedance can be provided.

### Eleventh Embodiment

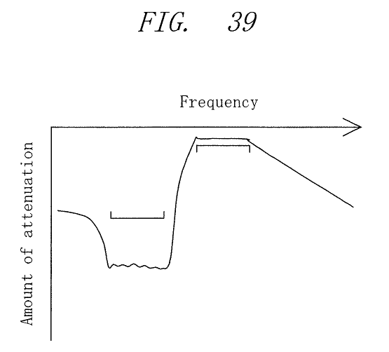

A high-frequency filter according to the eleventh embodiment will be described with reference to FIG. 37 to FIG. 45.

FIG. 37 is a circuit diagram of a high-pass filter using a beam-type resonator according to the eleventh embodiment described above.

A plurality of beam-type resonators 15 are electrically connected between two input/output terminals 13 in a parallel arm. Since the beam-type resonators 15 have small leakage of acoustic energy, the resistance value becomes approximately zero at a series resonance frequency, and the resistance value becomes approximately infinite at a parallel resonance frequency. Therefore, in the pass characteristics, an attenuation pole occurs in the series resonance frequency, and a pass loss minimum point occurs in the parallel resonance frequency.

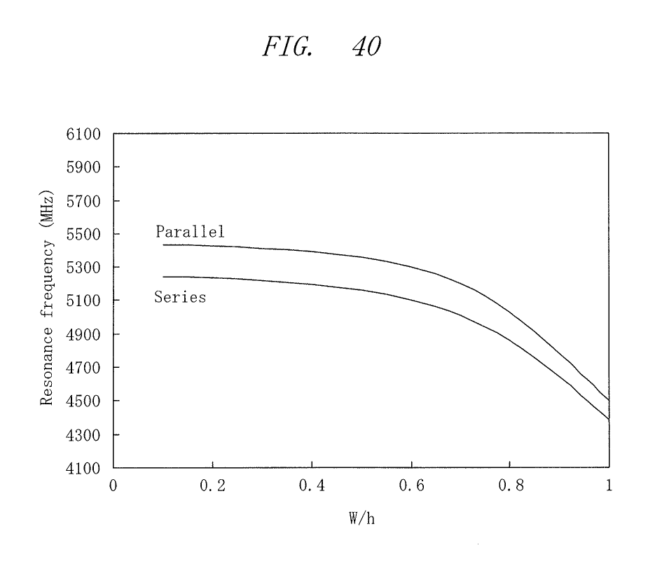

FIG. 38 is a graph for describing the pass characteristics of a low-pass filter in which the widths of all vibrating parts of the beam-type resonators according to the eleventh embodiment described above are set to have the same value. The beam-type resonator has large k2 and small acoustic energy leakage, and is spurious-free. Accordingly, the attenuation frequency band and the pass frequency band can be widened, and pass characteristics of respectively large attenuation amount therebetween and a small loss amount and being spurious-free can also be achieved.

FIG. 39 is a graph for describing pass characteristics of the low-pass filter in which the widths of the respective vibrating parts of the beam-type resonators according to the eleventh embodiment described above are set to have different values (seven types).

Focusing on the fact that the TWE mode has vibration components in the X axis direction unlike the conventional FBAR, the inventors of the present invention have studied in detail a relation between the series resonance frequency or the parallel resonance frequency and the shape of the vibrating part. As a result, it is found that, when the width W of the vibrating part is changed in the TWE mode, the series resonance frequency and the parallel resonance frequency are changed correspondingly. With the use of this, it is also found that, by connecting a plurality of beam-type resonators whose vibrating parts have different widths W in parallel, a low-pass filter having a plurality of attenuation poles can be achieved. This will be described below in detail with reference to FIG. 40.

FIG. 40 is a graph for describing a relation between the series resonance frequency or the parallel resonance frequency and dependency of the vibrating part on the width W. When a width W of the vibrating part is increased, the series resonance frequency and the parallel resonance frequency move to a low frequency side. The gap between the series resonance frequency and the parallel resonance frequency becomes maximum near 0.7 μm, and they simply decreases with approximately the same tendency. From this, in the beam-type resonator, the series resonance frequency and the parallel resonance frequency can be adjusted by the width W of the vibrating part without changing the thicknesses of the piezoelectric thin film, the upper metal film, and the lower metal film or without adding a new film.

Accordingly, a plurality of beam-type resonators having different series resonance frequencies and parallel resonance frequencies can be collectively manufactured by a common process. As shown in FIG. 39 described above, attenuation frequency band and pass frequency band can be further widened, and pass characteristics of further larger attenuation amounts therebetween and smaller loss amount can be achieved.

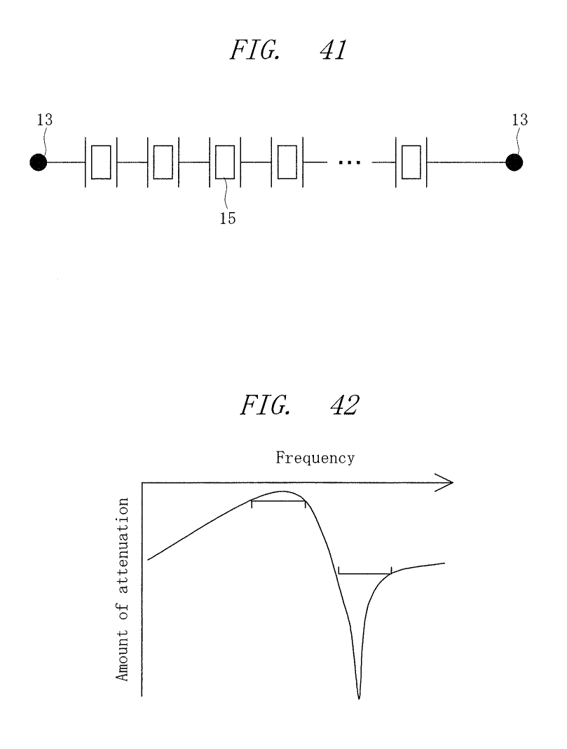

FIG. 41 is a circuit diagram of a low-pass filter in which many beam-type resonators according to the first to eleventh embodiments described above are connected in series. The plurality of beam-type resonators 15 are electrically connected between two input/output terminals 13 in a series arm. Therefore, in the pass characteristics, a pass loss minimum point occurs in the series resonance frequency, and an attenuation pole occurs in the parallel resonance frequency.

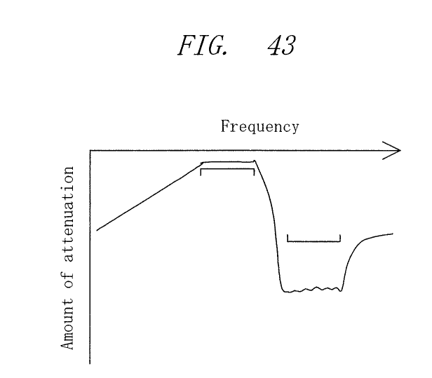

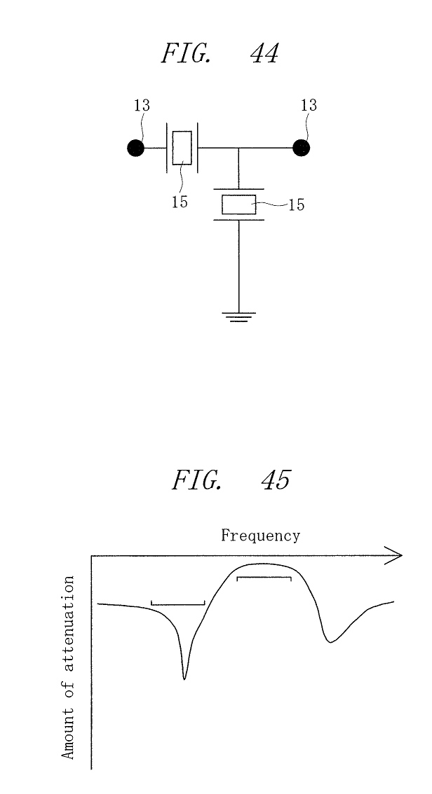

FIG. 42 is a graph for describing pass characteristics of a low-pass filter in which the widths of all vibrating parts of the beam-type resonators according to the eleventh embodiment described above are set to have the same value. The beam-type resonator has large k2 and small acoustic energy leakage, and is spurious-free. Accordingly, the attenuation frequency band and the pass frequency band can be widened, and pass characteristics of respectively large attenuation amount therebetween and a small loss amount and being spurious-free can also be achieved.

FIG. 43 is a graph for describing pass characteristics of the low-pass filter in which the widths of the respective vibrating parts of the beam-type resonators according to the eleventh embodiment described above are set to have different values (seven types). Attenuation frequency band and pass frequency band can be further widened, and pass characteristics of further larger attenuation amounts therebetween and smaller loss amount can be achieved.

FIG. 44 is a circuit diagram of a band-pass filter using the beam-type resonators according to the first to eleventh embodiments, and FIG. 45 is a graph for describing its pass characteristics. One beam-type resonator 15 is connected between two input/output terminals 13 in a series arm, and one beam-type resonator 15 is electrically connected in a parallel arm. A vibrating part in the series arm is set to have a width narrower than that of a vibrating part in the parallel arm. Thicknesses of a piezoelectric thin film, an upper metal film, and a lower metal film are set to have the same value. According to the eleventh embodiment, a plurality of beam-type resonators having different series resonance frequencies can be collectively manufactured by a common process. More specifically, a high-frequency filter excellent in electric characteristics can be provided at low cost.

Note that, while the case where the resonators are applied to a gamma-type band-pass filter has been described in FIG. 44, this is not meant to be restrictive. It goes without saying that the present eleventh embodiment can be used in, for example, a ladder-type filter in which resonators are connected in multiple steps, a balanced-type filter, or a branching filter and a similar effect can be achieved.

### Twelfth Embodiment

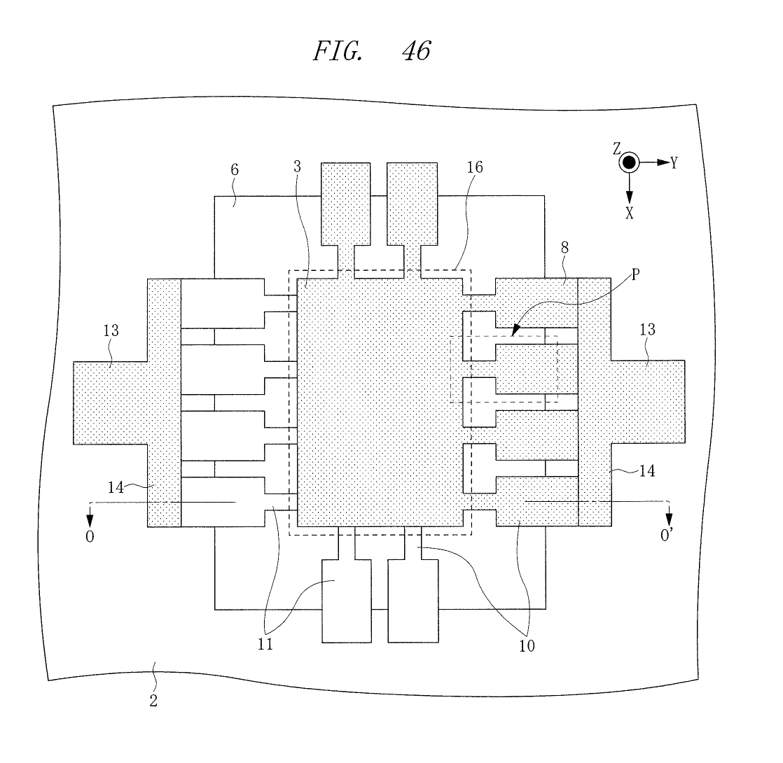

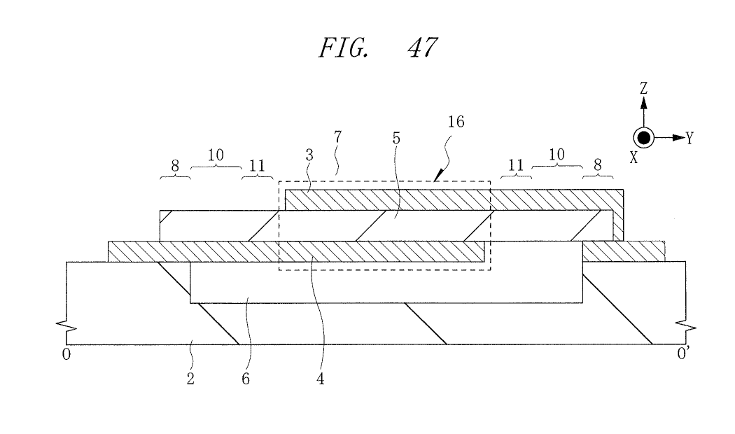

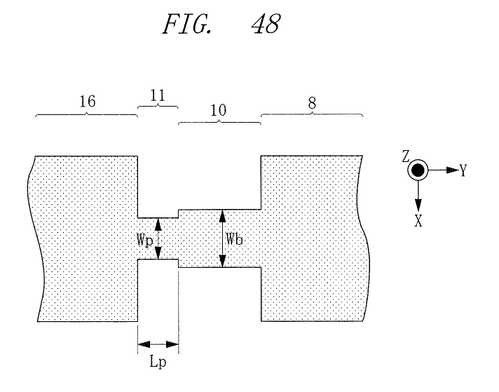

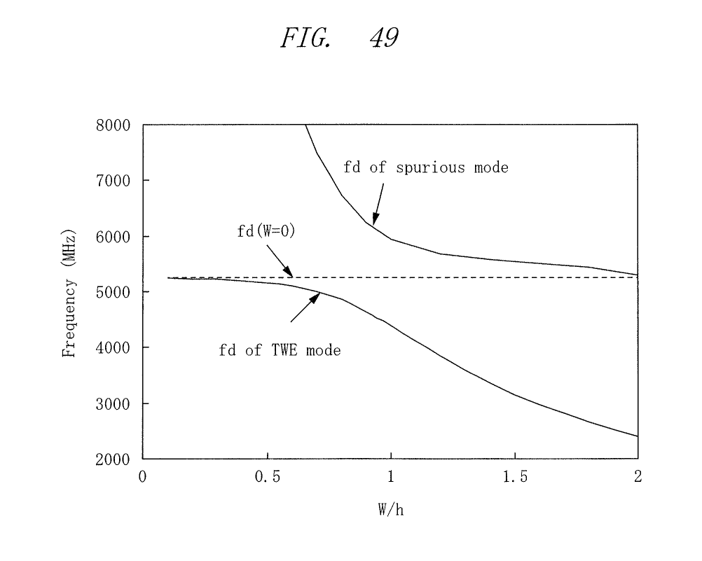

A beam-type resonator according to the twelfth embodiment will be described with reference to FIG. 46 to FIG. 48. FIG. 46 is a schematic top view of the beam-type resonator, FIG. 47 is a schematic cross-sectional view of the beam-type resonator taken along an O-O′ line of FIG. 46, and FIG. 48 is a schematic top view of a P area of FIG. 46.

As shown in FIG. 46 to FIG. 48, a conventional FBAR 16 is formed on an insulating substrate 2. The FBAR 16 is made up of a piezoelectric thin film 5 and a pair of an upper metal film 3 and a lower metal film 4 which are present with interposing this piezoelectric thin film 5 therebetween.

The dimensions of the FBAR 16 in an X axis direction and in a Y axis direction are set to be sufficiently larger than the dimension of that in a Z axis direction. Therefore, the FBAR 16 has a structure in a film shape (structure in which dimensions of a resonating part are sufficiently long in two directions (X axis direction and the Y axis direction) among the X, Y, and Z axis directions), and forms a planar structure.

The FBAR 16 has both ends in a plus X axis direction and a minus X axis direction and in a plus Y axis direction and a minus Y axis direction each physically connected to a fixing part 8 via a phase rotating part 11 and an acoustic insulating part 10.

The phase rotating part 11 is made up of the upper metal film 3 and the piezoelectric thin film 5 or the piezoelectric thin film 5 and the lower metal film 4. Also, the phase rotating part 11 has a width Wp set to, for example, 1.2 μm, and a length Lp set to, for example, 3.5 μm. Here, a natural resonance frequency of the FBAR 16 is a series resonance frequency of the FBAR 16.

Focusing on the fact that, when the widths of the phase rotating part 11 and the acoustic insulating part 10 are changed, a frequency fd and a frequency fb can be significantly changed correspondingly in the TWE mode unlike the conventional FBAR, and an insulating frequency band is wider than that of the FBAR 16, the inventors of the present invention have studied in detail a method of converting a thickness vibration mode of the FBAR 16 to the TWE mode. As a result, it is found that, by setting the natural resonance frequency of the phase rotating part 11 to be larger then one time and smaller than 1.05 times the natural resonance frequency of the FBAR 16, the thickness vibration mode can be changed to the TWE mode, thereby allowing entrance to the phase rotating part 11. It is also found that, by setting the natural resonance frequency of the acoustic insulating part 10 to be lower than the natural resonance frequency of the FBAR 16, the TWE mode propagating through the phase rotating part 11 cannot enter the acoustic insulating part 10.

As shown by the frequency fb of FIG. 9 described above, the natural resonance frequency of the FBAR 16 is higher than the natural resonance frequency of the TWE mode by approximately 10%. In order to make the natural resonance frequency of the phase rotating part 11 higher than the natural resonance frequency of the FBAR 16 by 0 to 5%, the phase rotating part 11 is made up of the upper metal film 3 and the piezoelectric thin film 5 or the piezoelectric thin film 5 and the lower metal film 4 in the twelfth embodiment. Furthermore, the main vibration mode of the phase rotating part 11 needs to be the TWE mode.

The natural resonance frequency of the acoustic insulating part 10 can be made lower than the natural resonance frequency of the FBAR 16 by setting the main vibration mode in the acoustic insulating part 10 to the TWE mode. In the twelfth embodiment, the phase rotating part 11 is made up of the upper metal film 3 and the piezoelectric thin film 5 or the piezoelectric thin film 5 and the lower metal film 4. Alternatively, it may be made up of the upper metal film 3, the piezoelectric thin film 5, and the lower metal film 4. In this case, in order to prevent excitation of the TWE mode by the acoustic insulating part 10, it is preferable that the upper metal film 3 and the lower metal film 4 are electrically short-circuited.

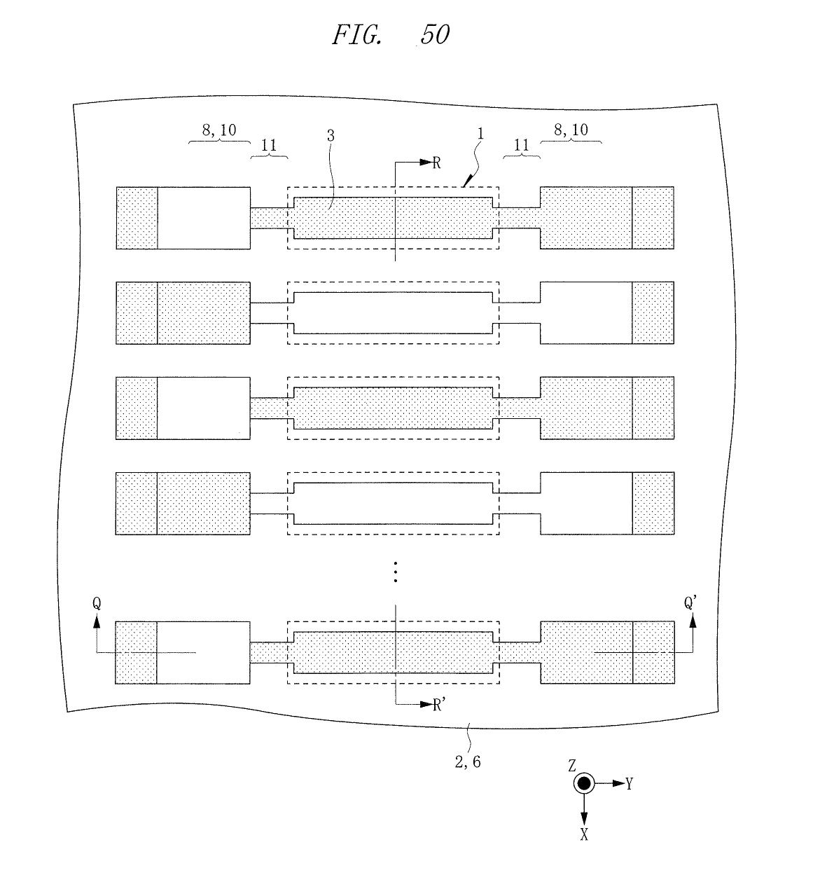

FIG. 49 is a graph for describing dependency of an acoustic mode of the acoustic insulating part of the beam-type resonator according to the twelfth embodiment on the width W. In the acoustic insulating part, a high-order TWE mode observed as spurious is present in addition to the TWE mode. Since the high-order TWE mode also has an acoustic propagation frequency band, the high-order TWE mode is preferably eliminated in order to cause the acoustic insulating part to stably function as an insulating layer.

As described above, according to the twelfth embodiment, by making W/h smaller than 2, the natural resonance frequency of the TWE mode and the natural resonance frequency of a higher-order TWE mode do not coincide with each other for any width W. More specifically, by making W/h smaller than 2, the acoustic insulating part can be caused to function as a stable acoustic insulating part. Similarly, also as for the phase rotating part, it can be caused to function as a stable phase rotating part by making W/h smaller than 2.

### Thirteenth Embodiment

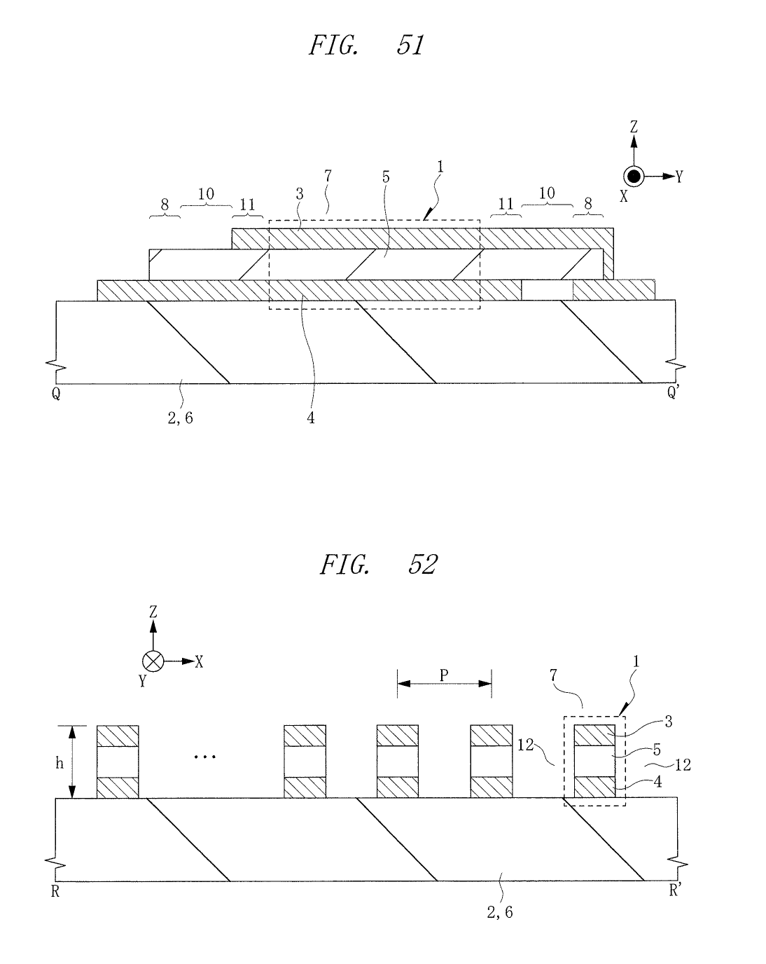

A beam-type resonator according to the thirteenth embodiment will be described with reference to FIG. 50 to FIG. 52. FIG. 50 is a schematic top view of the beam-type resonator, FIG. 51 is a schematic cross-sectional view of the beam-type resonator taken along a Q-Q′ line of FIG. 50, and FIG. 52 is a schematic cross-sectional view of the beam-type resonator taken along an R-R′ line of FIG. 50.

As shown in FIG. 50 to FIG. 52, a plurality of beam-type resonators are disposed in parallel to each other. Each beam-type resonator is disposed so that a voltage applying direction is oriented reversely to that of its adjacent beam-type resonator. When a center-to-center distance between adjacent two beam-type resonators is P, a natural resonance frequency of a vibrating part 1 of the beam-type resonator is f0, an elastic constant of an insulating substrate 2 is Cij, and a density is p, an equation P<(Cij/p)^{1/2})/(2×f0) is set. Therefore, an insulating substrate 2 functions as a lower acoustic wave reflector 6. Since an acoustic insulating part 10 is formed on a surface of the insulating substrate 2, the acoustic insulating part 10 functions also as a fixing part 8.

As described above, according to the thirteenth embodiment, since the insulating substrate 2 functions as the lower acoustic wave reflector 6, a process of manufacturing the lower acoustic wave reflector 6 can be omitted, and a beam-type resonator and a high-frequency filter using this can be provided at low cost.

### Fourteenth Embodiment

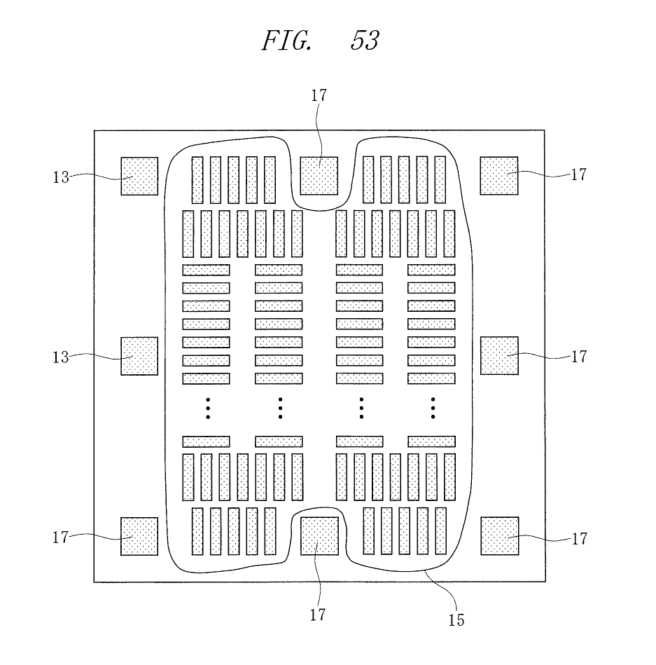

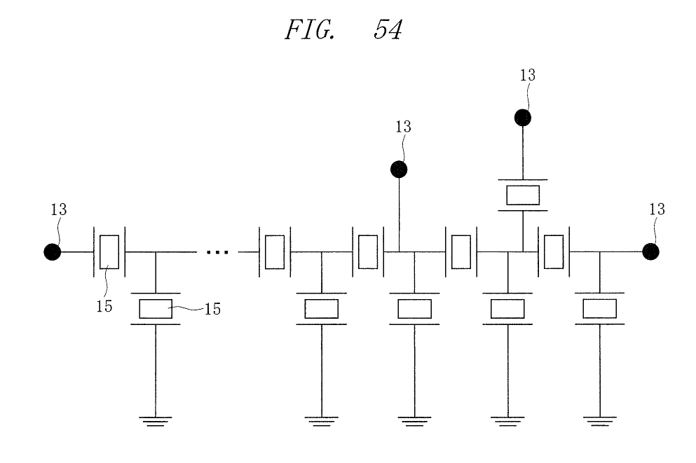

A high-frequency device according to the fourteenth embodiment will be described with reference to FIG. 53 and FIG. 54. FIG. 53 is a schematic top view of the high-frequency device, and FIG. 54 is an equivalent circuit diagram of the high-frequency device.

As shown in FIG. 53 and FIG. 54, on a silicon chip having a silicon oxide film on its surface, four input/output terminals 13 and four ground terminals 17 of a 100 μm square, and a plurality of beam-type resonators 15 are disposed. While electrical wiring lines are omitted in FIG. 53, each of these follows the equivalent circuit shown in FIG. 54, and the beam-type resonators 15 are electrically connected in a ladder type. The beam-type resonator group shown in FIG. 53 is made up of the beam-type resonators shown in the first to tenth embodiments described above. Therefore, the high-frequency device according to the fourteenth embodiment is made up of many beam-type resonators 15. The beam-type resonators 15 do not have to be oriented to the same direction, and can be disposed in the direction allowing easy electrical connection. Also, since each of the beam-type resonators 15 does not leak acoustic energy, the beam-type resonators 15 can be disposed closely. As a result, many beam-type resonators 15 can be disposed on a small chip. More specifically, since the chip size of the high-frequency device can be decreased, a small-sized, low-cost high-frequency device can be provided.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, the embodiments above have been described based on the example in which the piezoelectric thin film and the electrode have a specific thickness. However, if these film thicknesses are changed, the operation frequency or natural resonance frequency is shifted, but a relative relation in magnitude among the frequencies fd, fb, and ft is not changed. Therefore, the effect of the present invention is not restricted by the film thickness. Also, since the width W, the length L, and the thickness h are meaningful in their relative values, the effect of the present invention is not restricted by specific dimensions.

Also, the first embodiment to the tenth embodiment above have been described base on the example of a single-mode resonator made up of a set of a hot electrode and a ground electrode. However, it goes without saying that a similar effect can be achieved also in a multimode resonator made up of a plurality of hot electrodes. A typical multi-mode resonator can be achieved by, for example, forming a slit in an upper electrode near the center of an upper electrode. Alternatively, this can be achieved by connecting parts of the vibrating parts 1 of two closely-disposed beam-type resonators with the piezoelectric thin film 5, the upper metal film 3 or the lower metal film 4.

Still further, although the vibrating part 1, the fixing part 8, the acoustic insulating part 10, and the phase rotating part 11 are each made up of the upper metal film 3, the piezoelectric thin film 5, and the lower metal film 4 in the first embodiment to the tenth embodiment described above, it goes without saying that a similar effect can be achieved even when another substance is added. For example, a silicon oxide film may be added between the upper metal film 3 and the piezoelectric thin film 5, between the piezoelectric thin film 5 and the lower metal film 4, on the upper metal film 3, or under the lower metal film 4 of the vibrating part 1. In this case, an effect of improving temperature stability can be achieved. Alternatively, an insulating film or a dissimilar metal film may be added under the lower metal film 4. In this case, since a cavity as the lower acoustic wave reflector 6 can be stably formed and also the film quality of each of the upper metal film 3, the piezoelectric thin film 5, and the lower metal film 4 can be improved, loss of the beam-type resonator can be further reduced.

Still further, in the embodiments described above, air is used as an acoustic reflector. Since a difference in acoustic impedance is large between a solid and air with respect to the TWE mode and a reflection coefficient of approximately 100% can be achieved at its interface, this functions as the most excellent acoustic reflector. The same effect can be obtained also when using another gas or vacuum in place of air. On the other hand, when a Bragg reflector disclosed in Non-Patent Document 1 is used as an acoustic reflector, k2 is slightly smaller and the manufacturing cost is increased compared with those in the case of using air. However, it is possible to provide a beam-type resonator having sturdiness, which is a feature of the conventional SMR type, in which the number of processes is smaller than that of the SMR type, k2 is large, acoustic energy can be trapped in a resonating part, spurious resonance is not excited, and resonance frequency can be finely adjusted, and a high-frequency filter using the beam-type resonator.

### INDUSTRIAL APPLICABILITY

The present invention can be applied to a piezoelectric acoustic wave resonator having a high resonance frequency equal to or higher than 10 MHz and having a resonating part formed of a thin film, and to an acoustic wave device using the piezoelectric acoustic wave resonator.

### DESCRIPTION OF REFERENCE NUMERALS

1: vibrating part
2: insulating substrate
3: upper metal film (upper electrode)
4: lower metal film (lower electrode)
5: piezoelectric thin film
6: lower acoustic wave reflector (lower acoustic reflector)
7: upper acoustic wave reflector (upper acoustic reflector)
8: fixing part
9: fixing surface
10: acoustic insulating part
11: phase rotating part
12: side acoustic wave reflector (side acoustic reflector)
13: input/output terminal
14: connecting part
15: beam-type resonator
16: FBAR
17: ground terminal

1. A thin-film piezoelectric acoustic wave resonator including a vibrating part having a laminated structure made up of a piezoelectric thin film and a pair of an upper metal film and a lower metal film which are present with interposing a part of the piezoelectric thin film therebetween,
wherein the vibrating part has a first dimension in a first direction in a plane orthogonal to a thickness direction of the vibrating part and has a second dimension in a second direction orthogonal to the first direction, the first dimension is smaller than the second dimension, and the first dimension is smaller than a third dimension of the vibrating part in the thickness direction, and
an acoustic wave reflector is provided on each of an upper surface, a lower surface, and side surfaces of the vibrating part, a first fixing part mainly made of the same film as the piezoelectric thin film is provided at one end of the vibrating part in the second direction, and a second fixing part mainly made of the same film as the piezoelectric thin film is provided at the other end of the vibrating part in the second direction,
a first acoustic insulating part is physically connected between the one end of the vibrating part in the second direction and the first fixing part, and a second acoustic insulating part is physically connected between the other end of the vibrating part in the second direction and the second fixing part,
the first and second acoustic insulating parts have a structure in which the upper metal film, the piezoelectric thin film, and the lower metal film are laminated, and the acoustic wave reflector is provided on each of an upper surface, a lower surface, and side surfaces of the first and second acoustic insulating parts, and
a fourth dimension of the first and second acoustic insulating parts in the first direction is larger than the first dimension of the vibrating part in the first direction.

2. The thin-film piezoelectric acoustic wave resonator according to claim 1,
wherein the first dimension/the third dimension is 0.1 to 1.05.

3. The thin-film piezoelectric acoustic wave resonator according to claim 1,
wherein the first dimension/the third dimension is 0.2 to 0.9.

4. The thin-film piezoelectric acoustic wave resonator according to claim 1,
wherein the first dimension/the third dimension is 0.3 to 0.88.

5. The thin-film piezoelectric acoustic wave resonator according to claim 1,
wherein the acoustic wave reflector is gas or vacuum.

6. The thin-film piezoelectric acoustic wave resonator according to claim 1,
wherein the piezoelectric thin film is made of aluminum nitride, zinc oxide, lithium niobate, lithium tantalate, potassium niobate, tantalum pentoxide, lead titanate, or barium titanate.

7. The thin-film piezoelectric acoustic wave resonator according to claim 1,
wherein the upper metal film and the lower metal film are made of aluminum, copper, platinum, ruthenium, molybdenum, tungsten, or gold.

8. (canceled)

9. (canceled)

10. The thin-film piezoelectric acoustic wave resonator according to claim 1,
wherein a first phase rotating part is physically connected between the vibrating part and the first fixing part, and a second phase rotating part is physically connected between the vibrating part and the second fixing part,
the first and second phase rotating parts have a structure in which the upper metal film, the piezoelectric thin film, and the lower metal film are laminated, and the acoustic wave reflector is provided on each of an upper surface, a lower surface, and side surfaces of the first and second phase rotating parts, and
a fifth dimension of the first and second phase rotating parts in the first direction is smaller than the first dimension of the vibrating part in the first direction.

11. The thin-film piezoelectric acoustic wave resonator according to claim 1,
wherein a first phase rotating part is physically connected between the vibrating part and the first fixing part, and a second phase rotating part is physically connected between the vibrating part and the second fixing part,
the first phase rotating part has a structure in which the upper metal film and the piezoelectric thin film are laminated, and the acoustic wave reflector is provided on each of an upper surface, a lower surface, and side surfaces of the first phase rotating part,
the second phase rotating part has a structure in which the piezoelectric thin film and the lower metal film are laminated, and the acoustic wave reflector is provided on each of an upper surface, a lower surface, and side surfaces of the second phase rotating part, and
a fifth dimension of the first and second phase rotating parts in the first direction is larger than the first dimension of the vibrating part in the first direction.

12. The thin-film piezoelectric acoustic wave resonator according to claim 1,
wherein a first acoustic insulating part is physically connected between the one end of the vibrating part in the second direction and the first fixing part, and a second acoustic insulating part is physically connected between the other end of the vibrating part in the second direction and the second fixing part,
the first and second acoustic insulating parts have a structure in which the upper metal film, the piezoelectric thin film, and the lower metal film are laminated, and the acoustic wave reflector is provided on each of an upper surface, a lower surface, and side surfaces of the first and second acoustic insulating parts,
a first phase rotating part is physically connected between the vibrating part and the first acoustic insulating part, and a second phase rotating part is physically connected between the vibrating part and the second acoustic insulating part,
the first phase rotating part has a structure in which the upper metal film and the piezoelectric thin film are laminated, and the acoustic wave reflector is provided on each of an upper surface, a lower surface, and side surfaces of the first phase rotating part,
the second phase rotating part has a structure in which the piezoelectric thin film and the lower metal film are laminated, and the acoustic wave reflector is provided on each of an upper surface, a lower surface, and side surfaces of the second phase rotating part,
a fourth dimension of the first and second acoustic insulating parts in the first direction is larger than the first dimension of the vibrating part in the first direction, and
a fifth dimension of the first and second phase rotating parts in the first direction is larger than the first dimension of the vibrating part in the first direction.

13. The thin-film piezoelectric acoustic wave resonator according to claim 1,
wherein a first acoustic insulating part is physically connected between the one end of the vibrating part in the second direction and the first fixing part, and a second acoustic insulating part is physically connected between the other end of the vibrating part in the second direction and the second fixing part,
the first acoustic insulating part has a structure in which the upper metal film and the piezoelectric thin film are laminated, and the acoustic wave reflector is provided on each of an upper surface, a lower surface, and side surfaces of the first acoustic insulating part,
the second acoustic insulating part has a structure in which the piezoelectric thin film and the lower metal film are laminated, and the acoustic wave reflector is provided on each of an upper surface, a lower surface, and side surfaces of the second acoustic insulating part,
a first phase rotating part is physically connected between the vibrating part and the first acoustic insulating part, and a second phase rotating part is physically connected between the vibrating part and the second acoustic insulating part,
the first and second phase rotating parts have a structure in which the upper metal film, the piezoelectric thin film, and the lower metal film are laminated, and the acoustic wave reflector is provided on each of an upper surface, a lower surface, and side surfaces of the first and second phase rotating parts,
a fourth dimension of the first and second acoustic insulating parts in the first direction is larger than the first dimension of the vibrating part in the first direction, and
a fifth dimension of the first and second phase rotating parts in the first direction is smaller than the first dimension of the vibrating part in the first direction.

14. The thin-film piezoelectric acoustic wave resonator according to claim 10,
wherein a natural resonance frequency of each of the first and second phase rotating parts is larger than 1 time and smaller than 1.05 times a natural resonance frequency of the vibrating part.

15. A thin-film piezoelectric acoustic wave resonator including a vibrating part having a laminated structure made up of a piezoelectric thin film and a pair of an upper metal film and a lower metal film which are present with interposing a part of the piezoelectric thin film there between,
wherein the vibrating part has a first dimension in a first direction in a plane orthogonal to a thickness direction of the vibrating part and has a second dimension in a second direction orthogonal to the first direction, the first dimension is smaller than the second dimension, and the first dimension is smaller than a third dimension of the vibrating part in the thickness direction,
an acoustic wave reflector is provided on each of an upper surface, a lower surface, and side surfaces of the vibrating part, a first fixing part mainly made of the same film as the piezoelectric thin film is provided at one end of the vibrating part in the second direction, and a second fixing part mainly made of the same film as the piezoelectric thin film is provided at the other end of the vibrating part in the second direction,
the acoustic wave reflectors provided on the upper surface and the side surfaces of the vibrating part are gas or vacuum, and the acoustic wave reflector provided on the lower surface of the vibrating part is an insulating substrate, and
each of the plurality of vibrating parts is disposed so that a voltage applying direction is oriented reversely to that of its adjacent vibrating part.

16. The thin-film piezoelectric acoustic wave resonator according to claim 15,
wherein a plurality of the vibrating parts are disposed at predetermined intervals in the first direction on the insulating substrate, and when a center-to-center distance between adjacent two vibrating parts is P, a natural resonance frequency of the vibrating part is f0, an elastic constant of the insulating substrate is Cij, and a density is p, the center-to-center distance P is set as P<(Cij/p)^{1/2})/(2×f0).

17. (canceled)

18. (canceled)

19. (canceled)

20. (canceled)

21. A thin-film piezoelectric acoustic wave resonator including a vibrating part having a laminated structure made up of a piezoelectric thin film and a pair of an upper metal film and a lower metal film which are present with interposing a part of the piezoelectric thin film therebetween,
wherein the vibrating part has a first dimension in a first direction in a plane orthogonal to a thickness direction of the vibrating part and has a second dimension in a second direction orthogonal to the first direction, the first dimension is smaller than the second dimension, and the first dimension is smaller than a third dimension of the vibrating part in the thickness direction,
an acoustic wave reflector is provided on each of an upper surface, a lower surface, and side surfaces of the vibrating part, a first fixing part mainly made of the same film as the piezoelectric thin film is provided at one end of the vibrating part in the second direction, and a second fixing part mainly made of the same film as the piezoelectric thin film is provided at the other end of the vibrating part in the second direction,
a first acoustic insulating part is physically connected between the one end of the vibrating part in the second direction and the first fixing part, and a second acoustic insulating part is physically connected between the other end of the vibrating part in the second direction and the second fixing part,
the first acoustic insulating part has a structure in which the upper metal film and the piezoelectric thin film are laminated, and the acoustic wave reflector is provided on each of an upper surface, a lower surface, and side surfaces of the first acoustic insulating part,
the second acoustic insulating part has a structure in which the piezoelectric thin film and the lower metal film are laminated, and the acoustic wave reflector is provided on each of an upper surface, a lower surface, and side surfaces of the second acoustic insulating part, and
a fourth dimension of the first and second acoustic insulating parts in the first direction is larger than the first dimension of the vibrating part in the first direction.

22. The thin-film piezoelectric acoustic wave resonator according to claim 11,
wherein a natural resonance frequency of each of the first and second phase rotating parts is larger than 1 time and smaller than 1.05 times a natural resonance frequency of the vibrating part.

23. The thin-film piezoelectric acoustic wave resonator according to claim 12,
wherein a natural resonance frequency of each of the first and second phase rotating parts is larger than 1 time and smaller than 1.05 times a natural resonance frequency of the vibrating part.

24. The thin-film piezoelectric acoustic wave resonator according to claim 13,
wherein a natural resonance frequency of each of the first and second phase rotating parts is larger than 1 time and smaller than 1.05 times a natural resonance frequency of the vibrating part.
